(19) United States
(12) Patent Application Publication
(10) Pub. No.: US 2021/0232724 A1
(43) Pub. Date: Jul. 29, 2021

(54) Method and Apparatus for Specifying Locations for Objects, and Determining Routes for Connecting Mediums Between the Objects, in a Three-Dimensional Model of a Building

(71) Applicant: Katerra, Inc., Menlo Park, CA (US)

(72) Inventors: Patrick Tierney, Los Gatos, CA (US); Tyler Kent Sheldon, San Francisco, CA (US); Sungmin Kim, Morgan Hill, CA (US); Ward Vercruysse, Portola Valley, CA (US); Jumie Yuventi, San Francisco, CA (US); Sarveswara Rao Basa, Hayward, CA (US)

(21) Appl. No.: 17/228,572

(22) Filed: Apr. 12, 2021

Related U.S. Application Data
(63) Continuation-in-part of application No. 16/721,757, filed on Dec. 19, 2019.
Application No. 16/721,757 is a continuation-in-part of application No. 16/721,765, filed on Dec. 19, 2019.
Application No. 16/721,765 is a continuation-in-part of application No. 16/721,836, filed on Dec. 19, 2019.

(51) Int. Cl. G06F 30/18; G06F 30/13

(52) U.S. Cl. CPC G06F 30/18; G06F 30/13

(57) ABSTRACT

A method for defining a route for a connecting medium through a three-dimensional building, involving modeling the three-dimensional building as a two-dimensional array of panels, wherein any two panels in the array of panels are connected panels if a connecting medium can be directly routed from one panel to the other panel, a set of coordinates for each of one or more panels in the array of panels where a connecting medium can enter or exit the panel, and a union of the respective set of coordinates for each of the one or more connected panels in the array of panels where a connecting medium can be routed between the connected panels. The process selects one or more panels in the array through which to route the connecting medium based on the unions of the respective set of coordinates for each of the one or more connected panels in the array of panels.

### CLAIM OF PRIORITY

This patent application is a continuation-in-part of U.S. patent application Ser. No. 16/721,757 filed Dec. 19, 2019, entitled “Method and Apparatus for Providing a Cost-Optimized Route for an Electrical Cable in a Three-Dimensional Model of a Building”, U.S. patent application Ser. No. 16/721,765 filed Dec. 19, 2019, entitled “Method and Apparatus for Specifying a Location for an Electrical Device in a Three-Dimensional Model of a Building”, and U.S. patent application Ser. No. 16/721,836 filed Dec. 19, 2019, entitled “Method and Apparatus for Providing a Cost-Optimized Route for Defining a Detailed Route for an Electrical Cable in a Three-Dimensional Model of a Building”, the contents of which are incorporated herein by reference.

### TECHNICAL FIELD

Embodiments of the present invention relate to creating a plan for the locations of equipment used in a building, such as equipment, objects, components, or devices, relating to mechanical, electrical, plumbing, fire suppression (MEPF) systems, and cost effective and detailed routing of connecting mediums (e.g., electrical cables, pipes, ductwork, etc.) there between, in a panelized model of a three-dimensional building.

### BACKGROUND

Building project costing/pricing, material procurement, construction planning, and actual construction/installation is typically done based on construction standards, such as the Construction Specification Institute (CSI), MasterSpec (software distributed by Deltek for the American Institute of Architects (AIA)), and Uniformat (a standard for classifying building specifications, cost, estimating, and cost analysis in the US and Canada) specifications and two-dimensional (2D) plans and elevations. These plans and elevations typically do not capture all of the equipment, objects, components, or devices used, for example, in mechanical (including but not limited to heating, cooling, ventilation, exhaustion, water cooling/heating, humidity control or air filtration, refrigeration), electrical, plumbing, and fire suppression (MEPF) systems) and the interconnections that are needed to actually realize the systems. The “F” in MEPF includes, in addition to fire suppression systems, fire sprinklers, fire alarm, fire safety, or more generally fire protection, systems. These plans typically only capture major infrastructure equipment and devices that are visible/accessible to the end users or as needed to obtain a building permit. This lack of information can result in inefficiencies throughout the building project delivery including: inaccurate pricing since material and work has to be ‘estimated’ from historical benchmarks, over/under ordering of materials particularly those not shown in the drawings, non-ideal crew project management, and longer installation durations since installers need to figure out means and methods on site.

Building Information Modeling (BIM) is meant to help address these problems and improve project delivery efficiencies. However, more simply what is needed is:

1. Design documentation that accurately captures all of the equipment, devices, and interconnections that will represent a 100% constructed system design;

2. Designs that show where exactly all the devices are located in the building relative to other infrastructure, for example, structural framing data, etc.;

3. Work instructions associated with installation/interconnections; and

4. For prefabrication activities, discrete documentation per assembly capturing all of the above as it relates to the prefab environment.

### BRIEF DESCRIPTION OF THE DRAWINGS

Embodiments are illustrated by way of example, and not by way of limitation, and can be more fully understood with reference to the following detailed description when considered in connection with the figures in which:

FIG. 1 is a flow diagram in accordance with an embodiment of the invention.

FIG. 2 is a flow diagram in accordance with an embodiment of the invention.

FIG. 3 is a flow chart in accordance with one embodiment of the invention.

FIG. 4A is functional block diagram in accordance with one embodiment of the invention.

FIG. 4B is a graphical illustration of a structural frame model 411 in accordance with the embodiment described with respect to FIG. 4A.

FIG. 5A is flow chart in accordance with one embodiment of the invention.

FIG. 5B is an electrical power plan in accordance with one embodiment of the invention.

FIG. 5C is an electrical ceiling plan in accordance with one embodiment of the invention.

FIG. 5D illustrates all structural frames merged in a panel in accordance with one embodiment of the invention.

FIG. 5E illustrates all blockages merged in a panel in accordance with one embodiment of the invention.

FIG. 5F is a Bill of Materials (BOM) generated according to the process depicted in the flowchart in FIG. 5B.

FIG. 5G illustrates mounting locations in terms of a set of coordinates for each device on a panel in the architectural model according to one embodiment of the invention.

FIG. 5H illustrates a shop drawing of devices and their respective locations according to one embodiment of the invention.

FIG. 6 illustrates how output of one embodiment of the invention may be utilized.

FIG. 7 is a model hierarchy of objects according to one embodiment of the invention.

FIG. 8 provide a geometric systems definition in accordance with an embodiment of the invention.

FIG. 9 is pseudocode in accordance with one embodiment of the invention.

FIG. 10 is flow chart of one embodiment of the invention.

FIG. 11 depicts a data model for the floor, walls and ceiling in a three dimensional building in accordance with one embodiment of the invention.

FIG. 12 depicts further aspects of the data model for the floor, walls and ceiling in a three dimensional building in accordance with one embodiment of the invention.

FIG. 13 depicts further aspects of the data model for the floor, walls and ceiling in a three dimensional building in accordance with one embodiment of the invention.

FIG. 14 depicts further aspects of the data model for the floor, walls and ceiling in a three dimensional building in accordance with one embodiment of the invention.

FIG. 15 depicts further aspects of the data model for the floor, walls and ceiling in a three dimensional building in accordance with one embodiment of the invention.

FIG. 16 depicts a data model for a two-dimensional panel in accordance with one embodiment of the invention.

FIG. 17 depicts further aspects of the data model for a two-dimensional panel in accordance with one embodiment of the invention.

FIG. 18 depicts further aspects of the data model for a two-dimensional panel in accordance with one embodiment of the invention.

FIG. 19 depicts further aspects of the data model for a two-dimensional panel in accordance with one embodiment of the invention.

FIG. 20 depicts further aspects of the data model for a two-dimensional panel in accordance with one embodiment of the invention.

FIG. 21 depicts further aspects of the data model for a two-dimensional panel in accordance with one embodiment of the invention.

FIG. 22 depicts further aspects of the data model for a two-dimensional panel in accordance with one embodiment of the invention.

FIG. 23 depicts further aspects of the data model for a two-dimensional panel in accordance with one embodiment of the invention.

FIG. 24 is flow chart in accordance with one embodiment of the invention.

FIG. 25A is flow chart in accordance with one embodiment of the invention.

FIG. 25B is a connecting medium support BOM in accordance with one embodiment of the invention.

FIG. 25C is a shop drawing by structural framing data in accordance with one embodiment of the invention.

FIG. 25D is an installation drawing for individual electrical cables in accordance with one embodiment of the invention.

FIG. 26 is a graphical depiction of a diagram in accordance with one embodiment of the invention.

FIG. 27 is a model hierarchy of objects according to one embodiment of the invention.

FIG. 28 shows hole drilling details according to one embodiment of the invention.

FIG. 29 is pseudocode in accordance with one embodiment of the invention.

FIG. 30 depicts aspects of embodiments of the invention.

FIG. 31 depicts aspects of embodiments of the invention.

FIG. 32 depicts panel arrangements according to embodiments of the invention.

FIG. 33 depicts YawPanel arrangements according to embodiments of the invention.

FIG. 34 depicts YawPanel arrangements according to embodiments of the invention.

FIG. 35 illustrates a diagrammatic representation of a machine in the exemplary form of a computer system, in accordance with one embodiment of the invention.

### DETAILED DESCRIPTION

Embodiments of the invention specify a location for each of a plurality of MEPF objects. An MPEF object can be any physical object that is part of a mechanical, electrical, plumbing, or fire protection (MEPF) system, including pieces of equipment, objects, components, or devices in a plan for a three-dimensional (3D) building. Hereinafter, reference to simply “device” or “devices” is understood to encompass pieces of equipment, objects, components, or any apparatus or elements, relating to MEPF systems or the like to be installed in a building. Examples include load centers, light switches, electrical receptacles, Packaged Terminal Air Conditioner (PTAC) units, air handling units, heating/cooling units, water supply and drain lines, fire suppression and fire alarm lines and components such as sprinkler heads and alarms.

The method comprises: receiving an architectural model (AM) of the 3D building; receiving an annotated AM with structural design information, and MEPF design information, receiving structural framing data for a plurality of two-dimensional (2D) panels that comprise the 3D building based on the annotated AM; determining available locations in, on, or between, one or more of the plurality of 2D panels at which a device can be located according to the annotated AM and the structural framing data; specifying the location for each of the plurality of devices in, on, or between, one or more of the plurality of 2D panels based on the determined available locations in, on, or between, the one or more 2D panels; and adding to the structural framing data the specified location for each of the plurality of devices in, on, or between, the one or more of the plurality of 2D panels.

Additional embodiments of the invention provide for a method for defining a cost-optimized route for a connecting medium (such as a cable, wire, conduit, pipe, ducting, or plenum, etc.) through a three-dimensional building. The method comprises: modeling the three-dimensional building as: a two-dimensional array of panels, wherein any two panels in the array of panels are connected panels if a connecting medium can be directly routed from one panel to the other panel, a set of coordinates for each of one or more panels in the array of panels where a connecting medium can enter or exit the panel, and a union of the respective set of coordinates for each of the one or more connected panels in the array of panels where a connecting medium can be routed between the connected panels; and selecting one or more panels in the array through which to route the connecting medium based on the unions of the respective set of coordinates for each of the one or more connected panels in the array of panels.

Additional embodiments of the invention provide for a method for defining a detailed route for a connecting medium between devices in a plan for a three-dimensional (3D) building. The method comprises: receiving an architectural model (AM) of the 3D building; receiving an annotated AM with structural design information, and MEPF design information; receiving structural framing data for a plurality of two-dimensional (2D) panels that comprise the 3D building based on the annotated AM, the structural framing data comprising a location for each of a plurality of devices in, on, or between, one or more of the plurality of 2D panels; determining available areas in, on, or between, one or more of the plurality of 2D panels through which a connecting medium can be routed between respective locations of two or more of the plurality of devices; receiving cost-optimized connecting medium routing information for each of the plurality of 2D panels; receiving detailed connecting medium routing rules; defining a route for a connecting medium between respective locations of two or more of the plurality of devices in, on, or between, one or more of the plurality of 2D panels based on: the location for each of a plurality of devices in, on, or between, one or more of the plurality of 2D panels; the determined available areas in, on, or between, one or more of the plurality of 2D panels through which the connecting medium can be routed between respective locations of two or more of the plurality of devices; the cost-optimized connecting medium routing information for each of the plurality of 2D panels; and the detailed connecting medium routing rules.

Each of these above mentioned embodiments is described in further detail below.

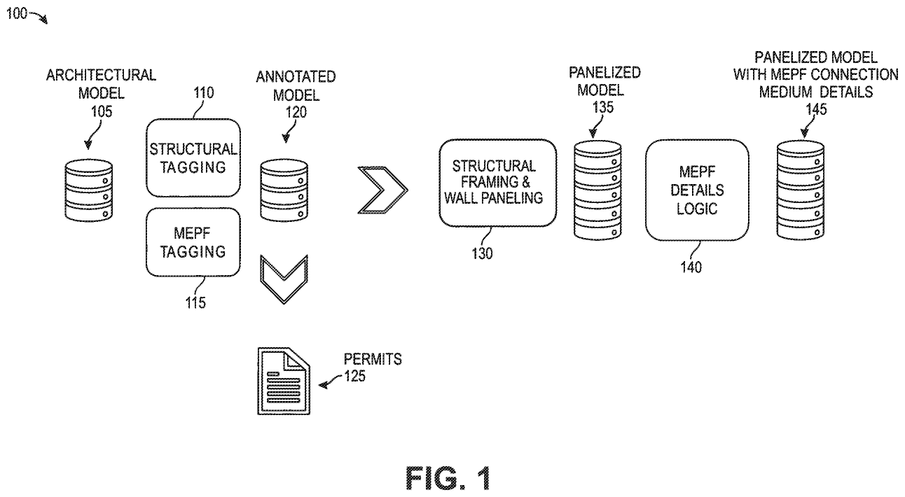

With reference with the flow diagram 100 in FIG. 1, embodiments of the invention receive as input an architectural model 105 for a building project, or building. The architectural model (AM) may be created with building information modeling (BIM) software, such as Autodesk Revit, available from Autodesk. The AM provides floor plans, elevations, sections, and three-dimensional views. In one embodiment, the BIM software may include structural design information, as well as MEPF (Mechanical Electrical Plumbing and Fire Suppression) or similar such design information (e.g., data routing system design, waste routing system design, compressed air routing system design), sufficiently detailed insofar as submitting and obtaining building permits. In another embodiment, the AM does not include the structural design information, MEPF design information, in which case, the AM is annotated with structural design information, or structural tagging 110, and MEPF design information, or MEPF tagging 115, thereby creating an annotated AM 120. In another embodiment, the AM includes high level structural design information, MEPF design information, but not sufficient information for the purpose of submitting and obtaining building permits 125, in which case, the AM is annotated with further detail regarding the structural design information (structural tagging 110), and MEPF design information (MEPF tagging 115), and an annotated AM 120 is created. The AM 105 or the annotated AM 120, as the case may be, is submitted to appropriate government authorities/agencies to obtain the necessary permits to begin construction.

According to an embodiment, the AM as augmented with the detail regarding the structural design information and MEPF design information, whether the AM 105, or the annotated AM 120, is further augmented at 130 to include structural framing data and wall paneling information for the three-dimensional building, and output as a panelized model 135 of the building.

Embodiments of the invention include connecting medium (e.g., wire, cable, pipe, or duct) routing logic to receive the panelized model 135 and add via MEPF details logic 140 the specific MEPF details to the model, including the location of MEPF devices, and routing information for connecting medium connecting the MPEF devices, and output a panelized model 145 of the building that includes MPEF connecting medium details. In one embodiment, the panelized model 145 is fed back to the BIM software, where a user can view all the additional details of the building project.

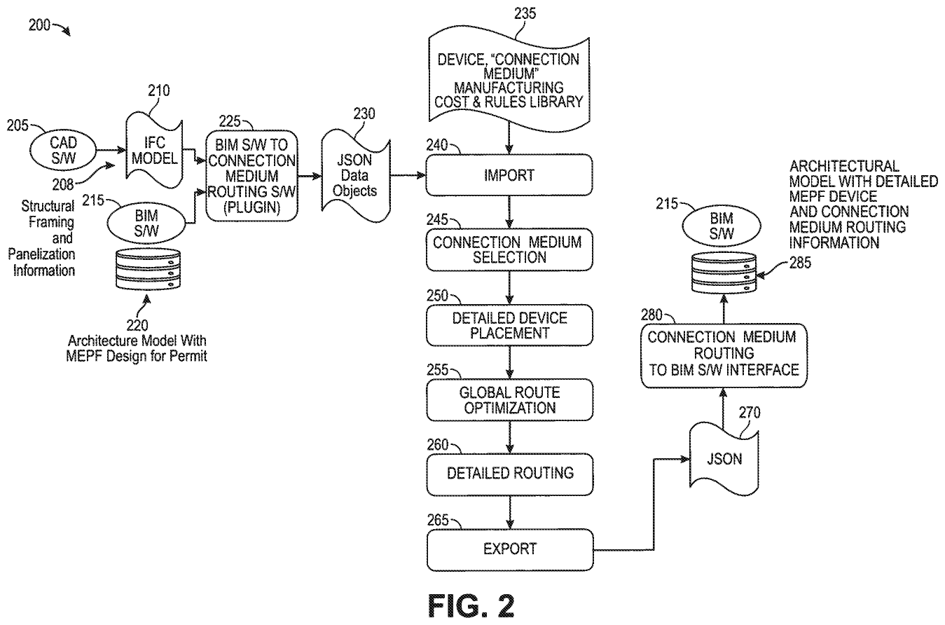

With reference to a more detailed flow diagram in FIG. 2, embodiments of the invention 200 receive as input an architectural model 220 for a building project, which may comprise one or more buildings. The architectural model (AM) may be created and/or modified with building information modeling (BIM) software 215, such as Autodesk Revit, available from Autodesk. In this embodiment, the AM includes design information for one or more MPEF systems, but structural design information is not present. Computer aided design (CAD) software 205, such as hsbcad software, available from hsbcad, Drongen, Belgium, receives structural framing data and, optionally, panelization information 208 and outputs a structural framing data and optional panelization data model 210 of such. In one embodiment the data model 210 is formatted according to the Industry Foundation Classes (IFC) data model. (The Industry Foundation Classes (IFC) data model is intended to describe architectural, building and construction industry data. IFC is a platform neutral, open file format specification that is not controlled by a single vendor or group of vendors. It is an object-based file format with a data model developed by buildingSMART (formerly the International Alliance for Interoperability, IAI) to facilitate interoperability in the architecture, engineering and construction (AEC) industry, and is a commonly used collaboration format in Building information modeling (BIM) based projects. The IFC model specification is open and available. It is registered by ISO and is an official International Standard ISO 16739-1:2018).

According to this embodiment, a BIM S/W to connecting medium routing software module, or BIM plug-in, 225, receives structural framing data and, optionally, panelization information from data model 210, and the AM 220, and produces data objects corresponding to components in the AM. In one embodiment, the data objects are formatted as JSON data objects 230, and include all the information the MEPF details logic 140 needs about the architectural model (AM) and structural framing data and, optionally, panelization information.

MEPF details logic 140 in FIG. 1 includes one or more of the functional blocks 240-265 in FIG. 2, as discussed further below. Embodiments of the invention receive, or import, at logic block 240 the JSON objects 230, including the structural framing data and, optionally, panelization information from data model 210, and further import at logic block 240 from one or more libraries 235 information about MEPF devices, connecting media such as electrical cables, wiring, piping, ductwork, etc., manufacturing costs, structural design rules, code rules, such as electrical code rules (e.g., National Electric Code (NEC) based rules; the NEC is a regionally adoptable standard for the safe installation of electrical wiring and equipment in the United States), plumbing code rules (e.g., National Standard Plumbing Code (NSPC), fire suppression/sprinkler rules (e.g., Life Safety Code rules such as the NFPA 101 consensus standard widely adopted in the United States published by the National Fire Protection Association), etc., and user rules. Logic blocks 240-265 then add specific MEPF details to the model, including, for example, the correct or appropriately sized connecting media, such as appropriately sized electrical cables, water pipes, HVAC ducts, etc., via connecting medium selection logic block 245; the specific location of MEPF devices via logic block 250 (wherein the location of one or more MEPF devices specified in the augmented AM imported into the connecting medium routing logic may be moved or adjusted, for example, for ease and cost of installation); and, routing information for the selected connecting media to connect the MEPF devices into various connecting media, e.g., electrical circuits or water pipes, via global routing optimization logic block 255 and detailed routing logic block 260. Embodiments then output, or export, via logic block 265 a panelized model of the building that includes MEPF connecting medium details in the form of JSON objects 270. In one embodiment, a logic block 280 communicates back to the BIM software 215 the panelized model of the building that includes MEPF connecting medium details, and the BIM software updates the architectural model 285 accordingly to include specific MEPF device location information and connecting medium routing information for connecting the MEPF devices. In one embodiment, logic block 280 is the BIM plug-in 225. In other embodiments, the logic block communicates with CAD software 205, which, in turn, updates IFC model 210 with the MEPF details, when then may be passed on to the BIM 215 or BIM plug-in 225, and added to the AM 220.

According to the embodiments, as further discussed below, global routing optimization logic block 255 determines, generally, through and/or between which panels to route the connecting media, and within each panel, where to route connecting media if applicable, and where to drill or use existing holes through which beams and studs of the panel, to route the connecting media. Detailed routing logic block 260 then determines exact routes for the connecting media, and means for routing and affixing the connecting media to beams and studs within the panels using, e.g., staples, zip ties, etc., and exactly where on the beams or studs to affix the connecting media.

### Location for an MEPF Object in a Three-Dimensional Model of a Building

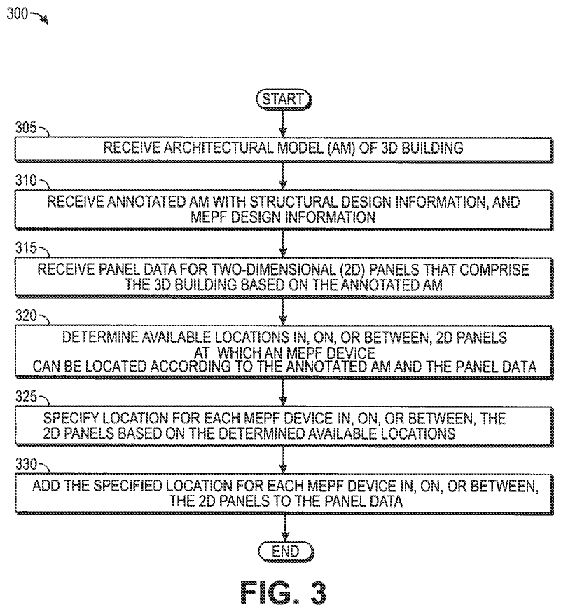

As discussed above, certain of the logic blocks illustrated in FIG. 2, in accordance with embodiments of the invention, work together to specify a location for each of a plurality of MEPF devices in an architectural model of a three-dimensional (3D) building project. With reference to FIG. 3, the method 300 comprises logic 305 for receiving an architectural model (AM) of a 3D building, and/or logic 310 for receiving an annotated AM that includes further structural design and MEPF design information, logic 315 for receiving structural framing data for a plurality of two-dimensional (2D) panels that comprise the 3D building based on the annotated AM. Logic 320 (corresponding to logic block 250 in FIG. 2) then determines available locations in, on, or between, one or more of the plurality of 2D panels at which an MEPF device can be located according to the annotated AM and the structural framing data, and logic 325 specifies the location for each of the plurality of MEPF devices in, on, or between, one or more of the plurality of 2D panels based on the determined available locations in, on, or between, the one or more 2D panels. Finally, logic 330 adds to the structural framing data the specified location for each of the plurality of MEPF devices in, on, or between, one or more of the plurality of 2D panels. In this manner, embodiments of the invention provide specified location data for each of a plurality of MEPF devices or components, such as an electrical circuit breaker panel, plumbing vents, drains, water heaters, water supply/shut-off valve(s), HVAC compressor, air handling units, fire suppression system discharge nozzles, gas supply/shut-off valve(s), etc.

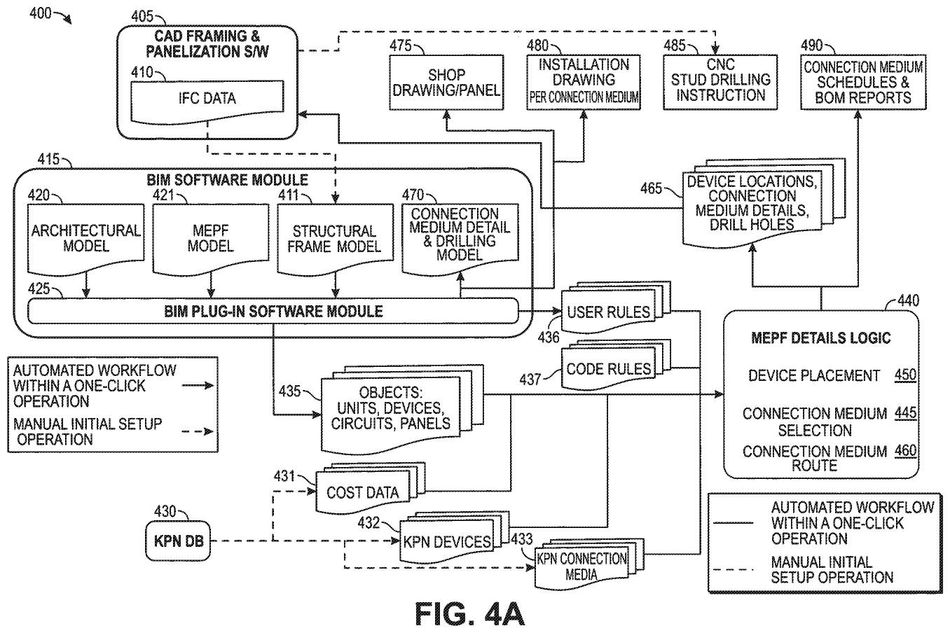

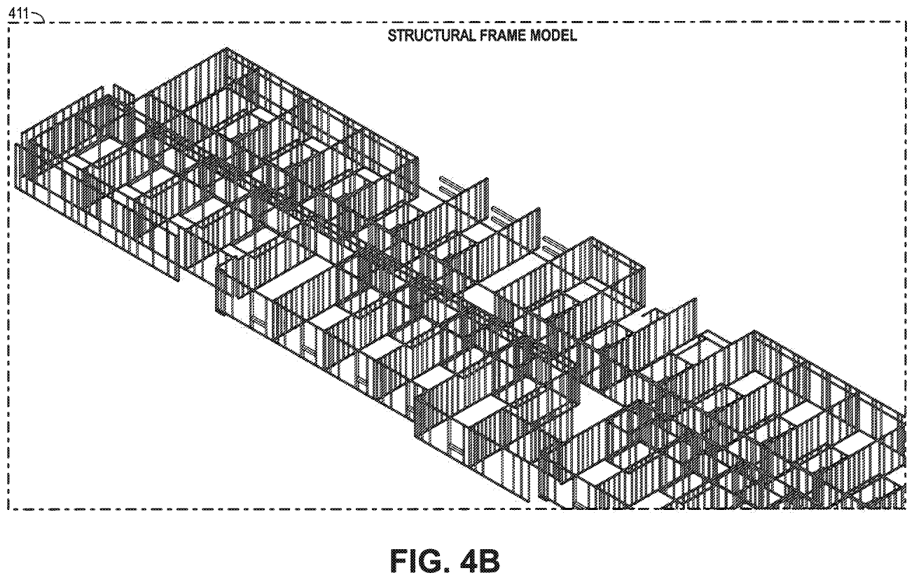

With reference to the functional block diagram in FIG. 4A, an embodiment of the invention 400 includes MEPF details logic 440 which, among other things, includes MEPF device placement logic 450 to specify a location, or place, for each of a plurality of MEPF devices in an architectural model for a three-dimensional (3D) building, connecting medium selection logic block 445 to select the correct or appropriately sized connecting medium, and connecting medium route logic 460 to determine exact connecting medium routes, and means for routing and affixing the connecting media to structural members, panels (including walls, ceilings, floors), and beams and studs within the panels using, e.g., straps, hangars, staples, zip ties, etc., and exactly where on the structural members, panels, beams or studs to affix the connecting media.

Embodiment 400 receives as input an architectural model 420 for a building project comprising one or more buildings. The architectural model (AM) may be created with building information modeling (BIM) software 415. In the illustrated embodiment, the BIM software does not include MEPF design information. Such information is input as part of the MEPF Model 421. BIM plug-in software 425 receives the MEPF Model 421 as input and augments the AM to include this information. Likewise, structural design information is not present in the AM 420. Computer aided design (CAD) structural framing data and optional panelization software 405 generates an IFC data model 410 of structural framing data and, optionally, panelization information. In one embodiment, the IFC data model 410 of the structural framing data and optional panelization data is not compatible with the BIM software and corresponding database, so the IFC data model 410 is converted into a structural frame model 411 that is compatible with the BIM software and corresponding database, and then added to the AM via the BIM plug-in software 425. In another embodiment, the IFC data model is compatible with the BIM software and database and so is input or incorporated directly into the database by BIM plug-in software 425 to augment the AM to include the structural design information. FIG. 4B illustrates one embodiment of structural frame model 411.

The BIM plug-in software 425 receives the architectural model 420, the structural framing data and optional panelization information in structural frame model 411, and the MEPF design details in MEPF Model 421, and generates data objects 435, such as data objects for electrical or plumbing units, electrical or plumbing devices, electrical circuits or plumbing pipe routes, and wall panels. This information or these data objects are input to and used by the MEPF details logic 440, in particular, the MEPF device placement logic 450, to locate or place the MEPF devices within, on, or between, the panels. Using the electrical part of the MEPF systems as an example, the following are examples of electrical device information objects that may be input to the MEPF device placement logic 450:

electrical device categories, such as: “LOAD_CENTER”, “RECEPTACLE”, “SWITCH”, “LIGHTING”, “LOWVOLTAGE”, “JUNCTION”, “OTHER”;

electrical device mount types, such as: “WALL”, “CEILING”, “FLOOR”, “WALL_SURFACE”, “OFF_WALL”;

electrical device dimensions; and

cable access locations for each device.

Similar such objects are also input to the MEPF device placement logic 450 for other MEPF systems such as plumbing objects, mechanical objects, fire suppression objects, fire alarm objects, etc. Embodiments of the invention receive at MEPF details logic block 440 the data objects 435, including the structural frame model 411, and further from one or more libraries, user control rules 436 and building code rules 437, such as electrical code (e.g., NEC) rules, plumbing code rules (e.g., NSPC), or fire suppression/sprinkler rules (e.g., NFPA 101). User control rules are control parameters that a user can input to control the MEPF device placement logic 450 in terms of exactly where to place MEPF devices. For example, user rules might include allowable locations for drilling holes in beams or studs, and the maximum diameter and length of any such holes.

A known product number (KPN) database 430 provides corresponding part numbers for each object 435, whether the KPN for an MEPF device 432, or the KPN for connecting media 433, and costs data 431 for each device or connecting medium, to the MEPF details logic 440.

MEPF device placement logic 450 generates the specific location of MEPF devices based on the user rules and code rules, and outputs the specific MEPF device locations at 465. This information, in turn, is provided to CAD structural framing data and optional panelization software 405, wherein a CAD user can modify the Structural frame IFC data 410 to take into consideration new details regarding the actual placement, or location, of the MEPF devices. The Structural frame IFC data 410, in turn, may be converted to structural frame model 411 data and added to the BIM by BIM plug-in software 425, which updates the connecting medium detail and drilling model 470 for the BIM accordingly.

According to one embodiment, the user rules may specify a prioritization scheme for generating the specific location of MEPF devices based on MPEF device type and/or size. For example, the user rules may require first locating the largest MEPF devices, such as HVAC air handling units or compressors, water heaters, electrical circuit breaker panels, etc., or first locating MEPF devices based on code requirements, such as locating an electrical circuit breaker panel within the required maximum distance to the exterior electrical meter, or near the mast through which power is connected to a home from a nearby power line, or locating a just in time water heater within a certain distance of the plumbing fixtures to which it is to supply heated water. Additionally, or optionally, the prioritization scheme for generating the specific location of MEPF devices is based on the cost, or complexity of installing, connecting medium for a specific type of MPEF system. For example, HVAC ducting occupies more space, requires a larger turn radius than, and may be more expensive than water pipe or electrical wiring/conduit for a given length, and so location of the HVAC components is prioritized over the location of an electrical receptacle or on/off switch, where there is less cost, and more ease/flexibility in routing electrical wiring to the electrical receptacle or on/off switch.

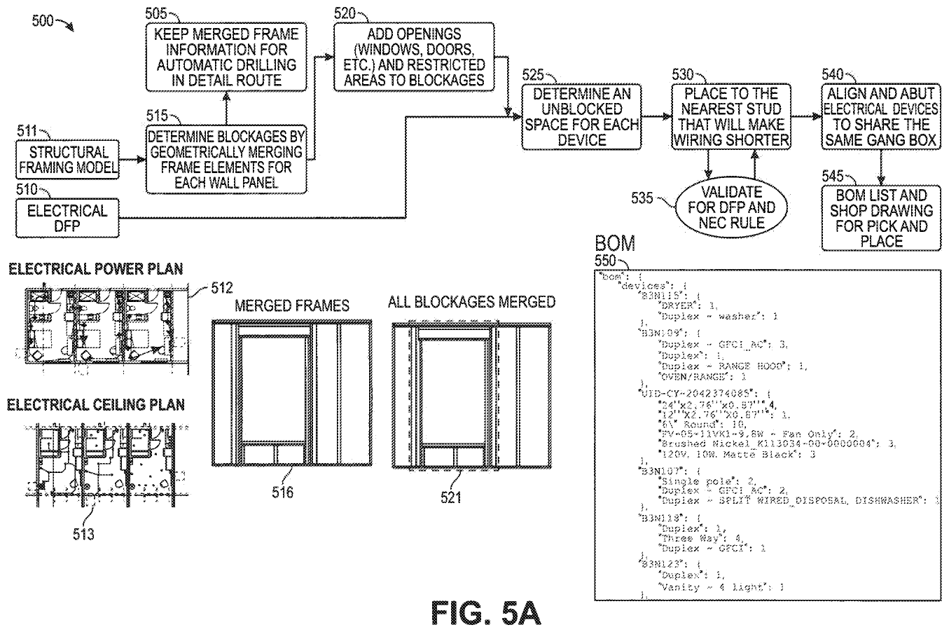

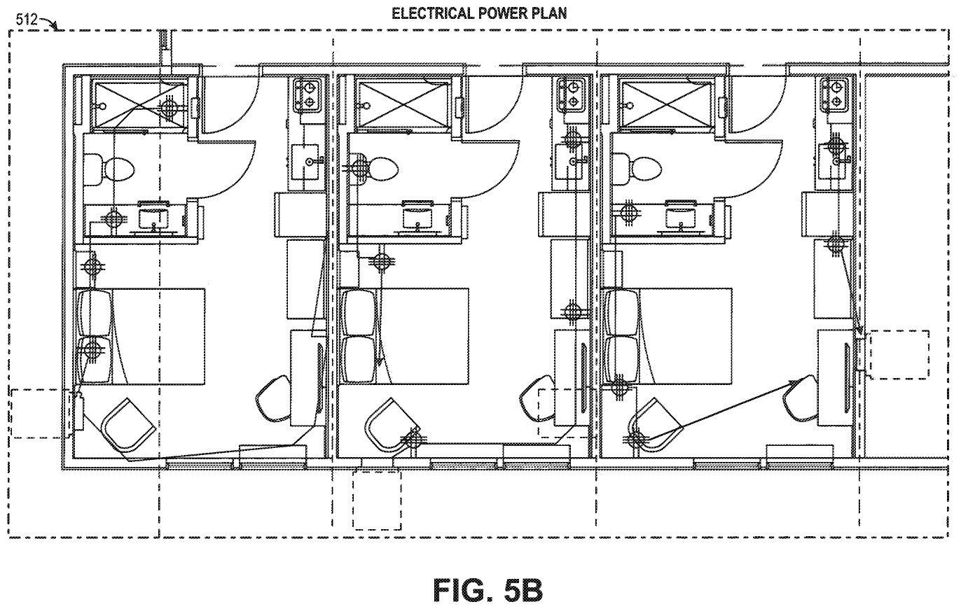

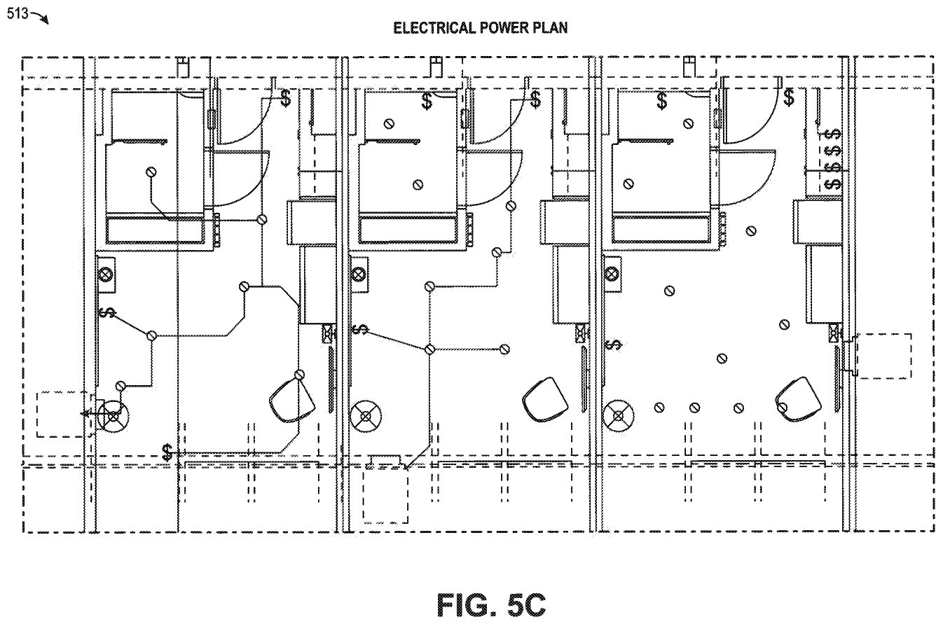

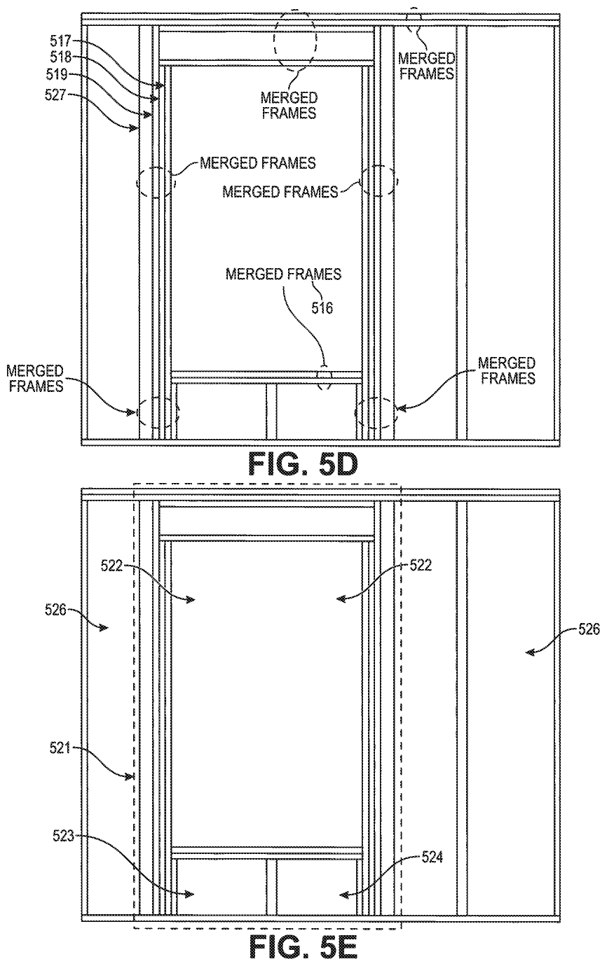

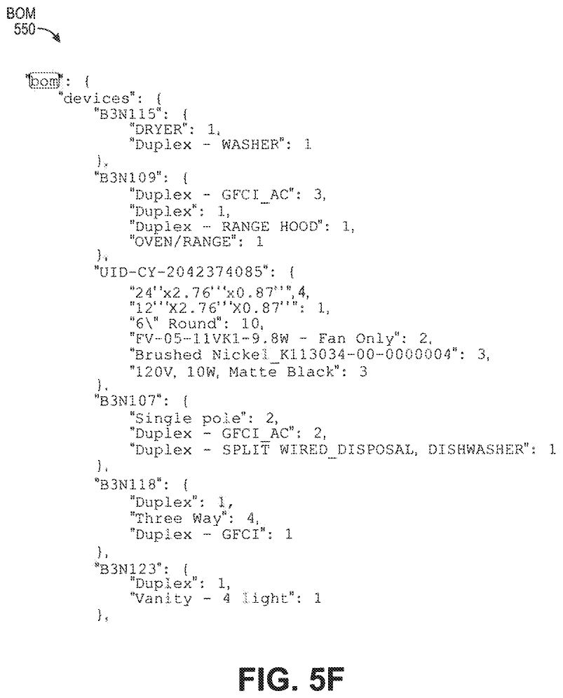

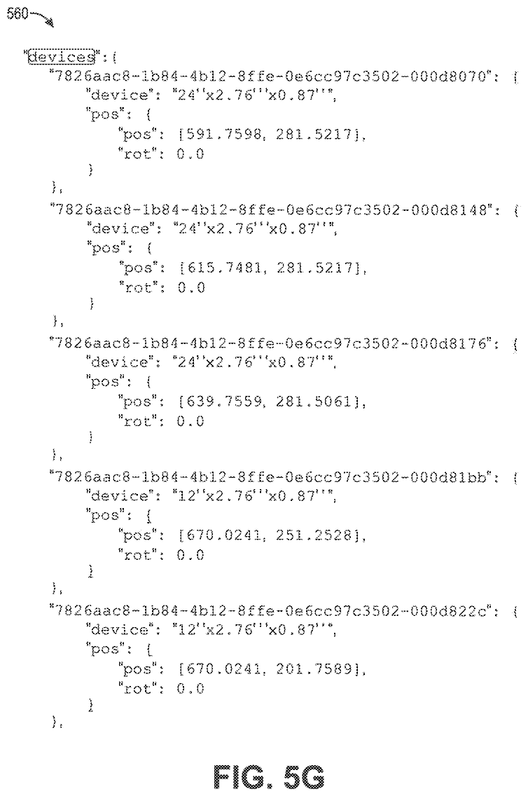

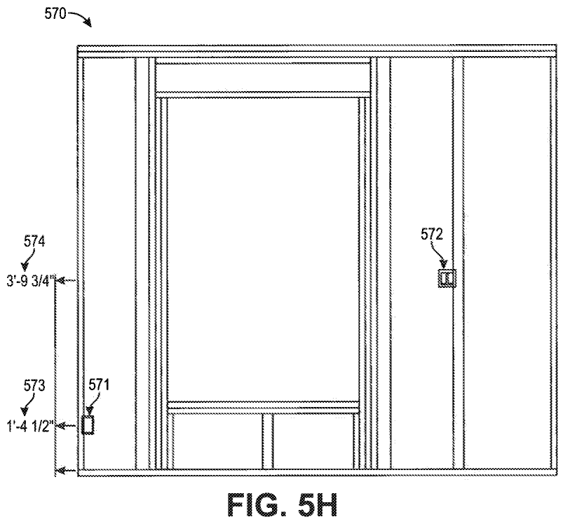

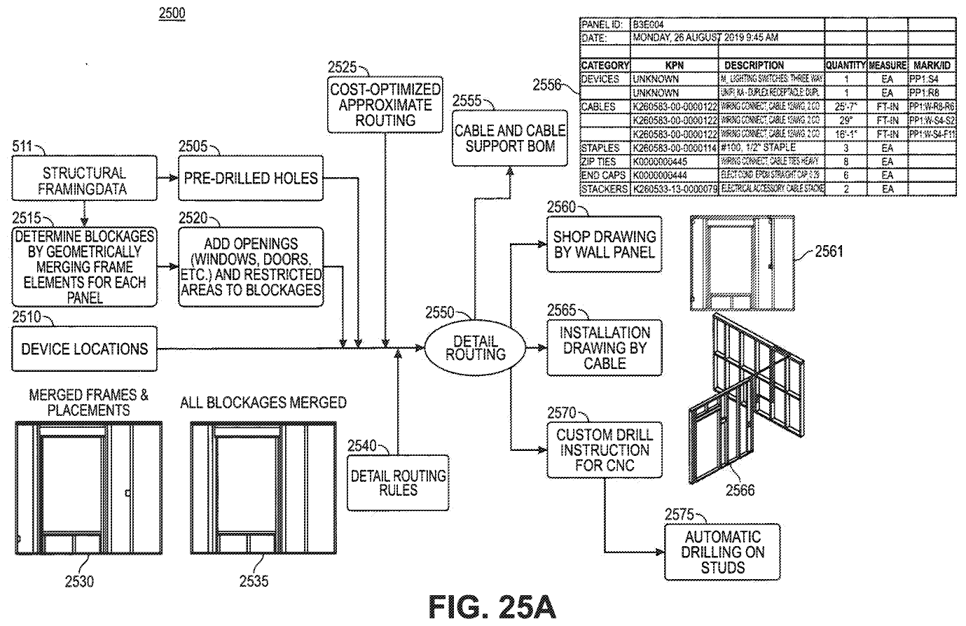

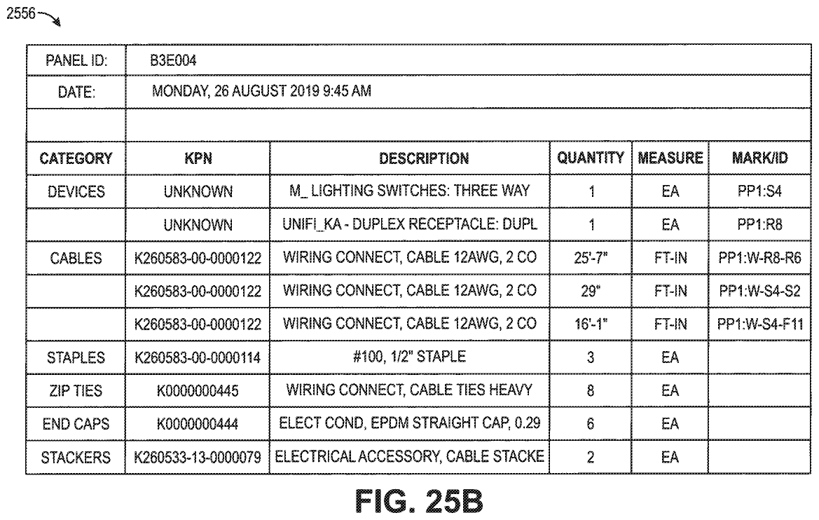

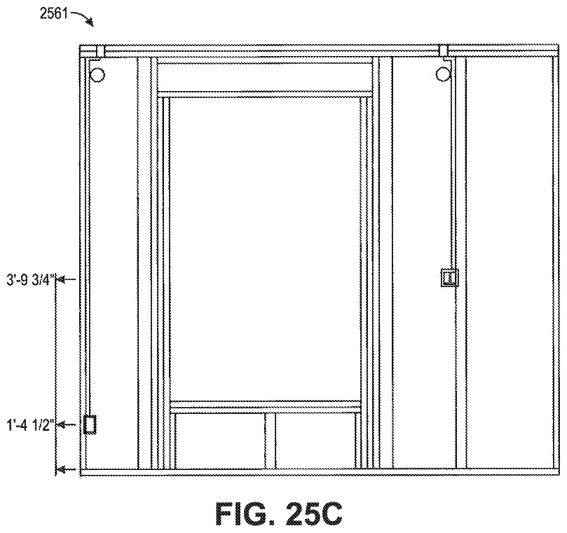

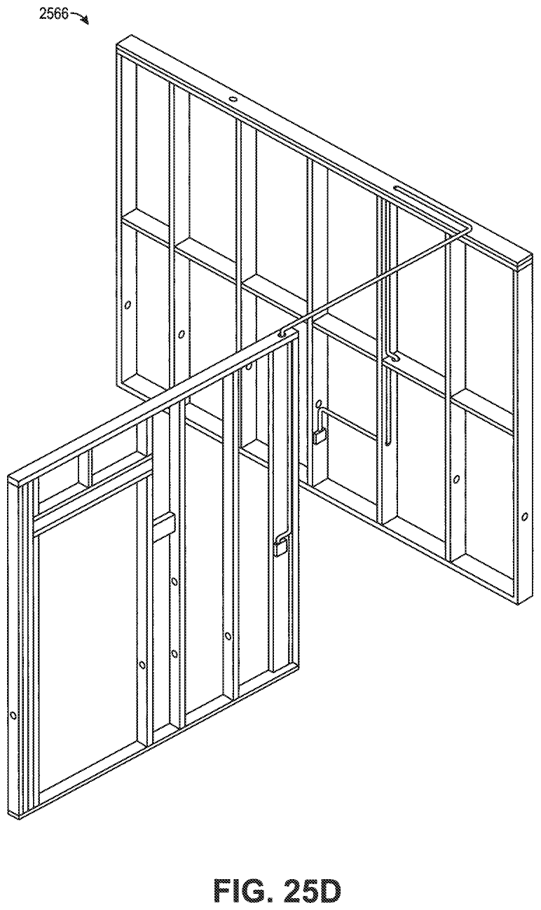

With reference to FIG. 5A, one embodiment 500 for MEPF device placement logic 450 is described as follows, using the electrical system as an example. Similarly, the embodiment 500 for MEPF device placement logic 450 as described as follows is equally applicable to other MEPF systems, such as a plumbing system or HVAC system. The process receives structural framing data model 511, and MEPF design information such as electrical design information 510, wherein the MEPF design information such as the electrical design information is at least as detailed as needed for submitting and obtaining building permits, such as electrical permits (Electrical Design for Permit—Electrical DFP). Examples of electrical design information are illustrated at 512 and 513 in FIGS. 5B and 5C, respectively. Similar design information is received for other MEPF systems such as plumbing and HVAC systems, for example, the design information for an HVAC system may include one or more HVAC compressors and one or more air handling units, and their respective sizes. Logic 515 identifies individual structural frame blockages, e.g., structural framing data members of the building, including panels, beams, studs, plates, trusses, rafters, joists, etc., where a MEPF device, such as a HVAC air handling unit, or an electrical device, cannot be placed, and merges adjacent structural frame blockages 516. For example, with reference to FIG. 5D, respective abutting vertical studs 517, 518, 519, and 527 are, individually, a structural frame blockage in the sense that a MEPF device such an electrical device cannot be placed over the studs. Embodiments of the invention group, or geometrically merge, these individual structural frame blockages to represent the structural frame blockages as a single structural frame blockage 516 for the purpose of locating a MEPF device such as an electrical device. This information is also saved at logic 505 and provided to similar logic 2515 in the connecting medium routing logic 460 discussed further herein with reference to FIGS. 4A and 25A.

With reference to FIGS. 5A and 5E, logic 520 identifies additional areas, such as opening 522 (windows, doors), and restricted or undesirable areas 523, 524 where a MEPF device such as an electrical device cannot, should not, or preferably should not, be located, such as under a window, and merges adjacent areas as single area blockage. Area blockages, in turn, as the case may be, are merged with the adjacent merged structural frame blockages. For example, with reference to FIG. 5E, structural frame blockages 516 and areas 522, 523 and 524 are merged into one monolithic blockage 521. A MEPF device such as an electrical device will not be placed over or within blockage 521. Embodiments of the invention group, or geometrically merge, the structural frame blockages and area blockages to represent the blockages as a single blockage 521 for the purpose of locating MEPF devices.

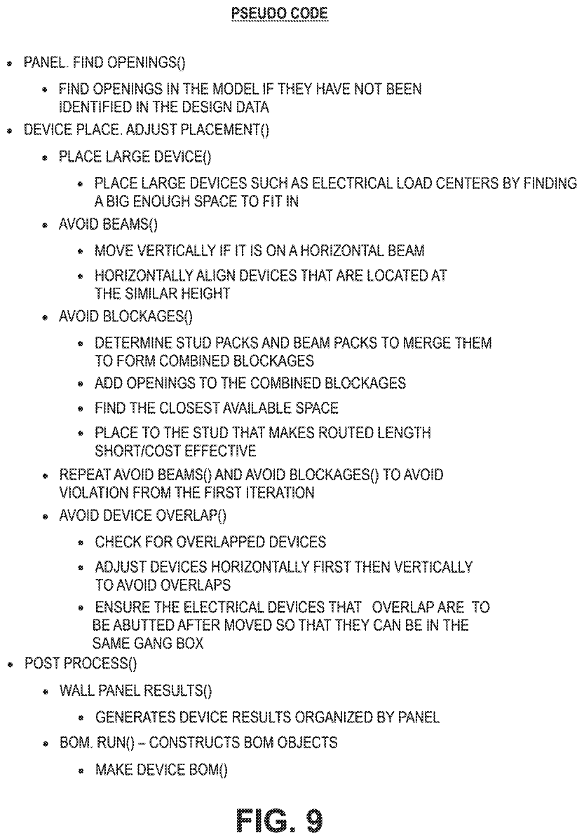

With further reference to FIGS. 5A and 5E, logic 525 identifies unblocked, or open spaces 526 in which a MEPF device such as an electrical device can be located. In one embodiment, the logic identifies a particular space or portion thereof, such as in an attic, interstitial space, or panel, in which to locate each MEPF device. Logic 530 then determines, based on the structural framing data and optional panelization information, the blockages, and the unblocked spaces, the nearest structural framing data member, e.g., stud, to which to mount each MEPF device. As an example, with reference to an electrical system, according to embodiments, an electrical box is mounted to a nearest structural framing member. One or more electrical devices, such as a receptacle, switch, a lighting device, is installed in the electrical box. In other instances, the electrical device is a box of some sort itself, such as a load center or junction box. The mounting location may be specified in terms of a set of coordinates 560 for each electrical device on a panel in the architectural model, as illustrated in FIG. 5G. Similar mounting locations may be specified in terms of a set of coordinates 560 for each device in another system, such as a plumbing system, on a panel in the architectural model, just the electrical devices illustrated in FIG. 5G. In one embodiment, the logic 530 determines the nearest stud, and location thereof, for each MEPF device such as an electrical device taking into consideration the shortest and/or most cost effective route for the connecting medium, e.g., with reference to an electrical system, the shortest and/or most cost effective route for the electrical wire or cable that connects the electrical device to an electrical circuit, and further taking into consideration user rules in one embodiment. In one embodiment, validation logic 535 confirms the selected location of the nearest stud conforms to the appropriate permits and code rules. According to one embodiment, logic 540 aligns, abuts, groups MEPF devices such as electrical devices, e.g., switches and/or electrical outlets (wall plugs), to be adjacent one another, or share the same location, e.g., mounted in the same “gang box” that houses two or more electrical devices (e.g., a combination of an outlet/switch, or two or more outlets/switches in one location). FIG. 9 provides example pseudocode for the logic described with reference to FIG. 5A, using electrical devices as an example. Similar pseudocode may be used to guide placement of other MEPF devices such as plumbing fixtures or HVAC components.

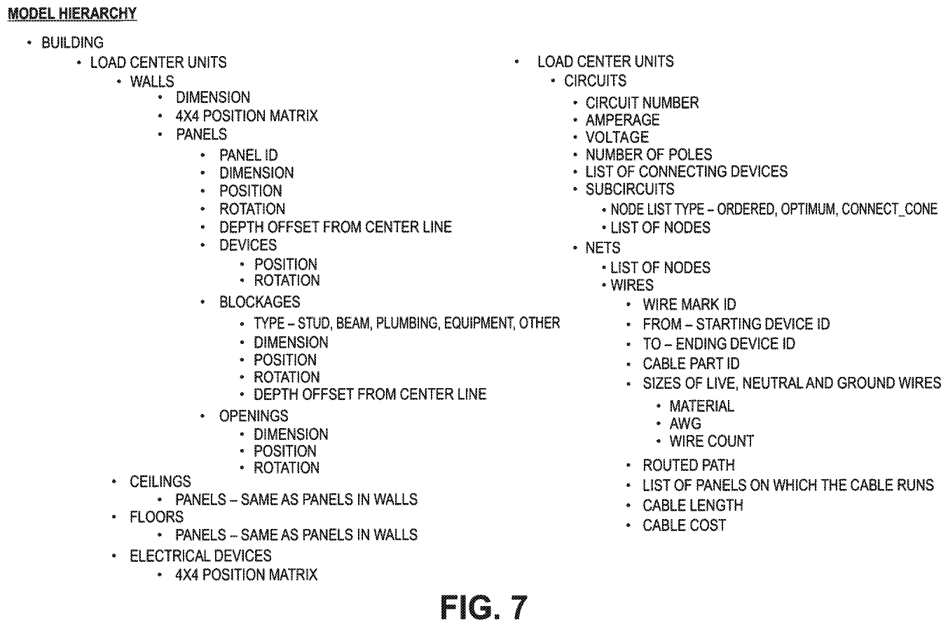

The process performed by logic blocks 515-540 provide for updating the structural framing data model 511 with significant details regarding the model. FIG. 7 illustrates a hierarchy for the model, and where within the hierarchy the information generated by logic blocks 515-540 is located, e.g., location of blockages and openings in panels for walls, ceilings, floors, and location of MEPF devices.

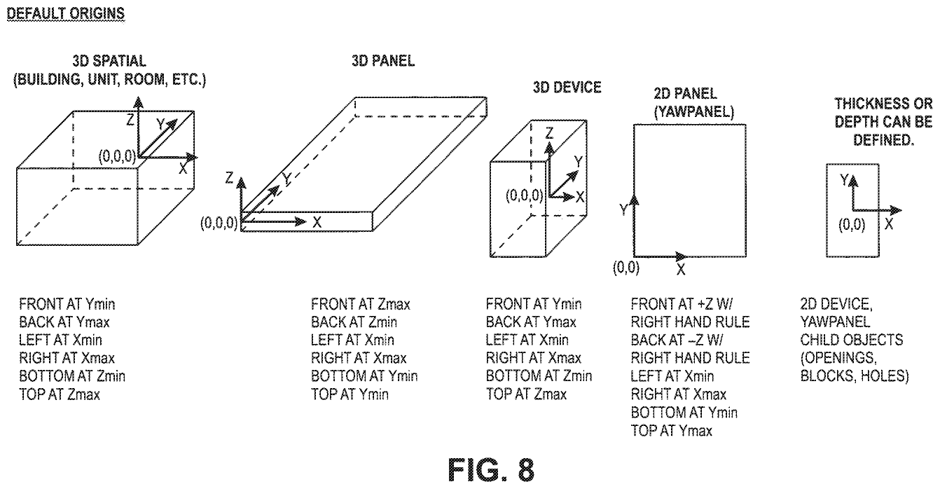

As for the mounting locations for MEPF devices being specified in terms of a set of coordinates 560 on a panel in the architectural model, as illustrated in FIG. 5G, the benefit of using a common, consistent geometric system definition for data objects thereof, e.g., data objects for the 3D architectural model of the building, its ceilings, floors, walls, panels thereof, and MEPF devices therein or thereon, is understood. FIG. 8 provides an example of a geometric system definition for these objects, in particular, the default origins according to a three dimensional x, y, and z coordinate system. Note that an object's origins may be set differently than the default origins as long as the object's own child objects and own instances are correctly placed according to the origins. For example, the origin of a unit may be set at the load center location. Using this system, a point and/or plane of reference is provided for the front, back, left, right, bottom and top of each building, its ceilings, floors, walls, panels thereof, and MEPF devices therein or thereon.

Finally, using the electrical system as an example, with reference to FIGS. 4A, 5A and 5F, logic 545 outputs the locations of all the electrical devices. Similar output is produced for other systems such as the locations of all the plumbing fixtures, or HVAC components. In one embodiment the locations of all the devices, such as electrical devices, is set forth as a list accompanying or in a Bill of Materials (BOM) report 490, 550 that may be used, e.g., by the BIM software, to identify materials and equipment, as well as quantities and costs thereof. With reference to FIGS. 4A, 5A, and 5H, again using the electrical system as an example, logic 545 may also prepare at least relevant portions of so-called electrical “Shop Drawings” 475, 570, identifying electrical devices 571, 572 and their respective locations 573, 574. Logic 545 may also prepare at least relevant portions of shop drawings identifying devices for other systems, such a sprinkler heads for a fire suppression system, or alarm locations for a fire alarm/CO2 alarm system, and their respective locations. Alternatively, such information is part of the report 465 that, in turn, is fed to CAD software 405, and used to update the structural frame model 411, which the BIM plug-in software incorporates into the architectural model, and from which shop drawings, such as the electrical shop drawings, may be generated.

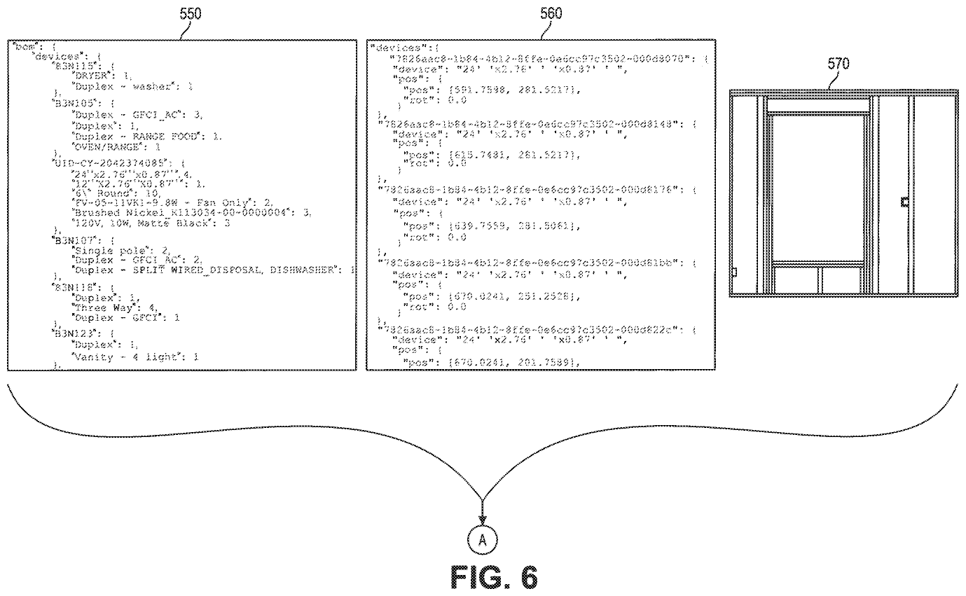

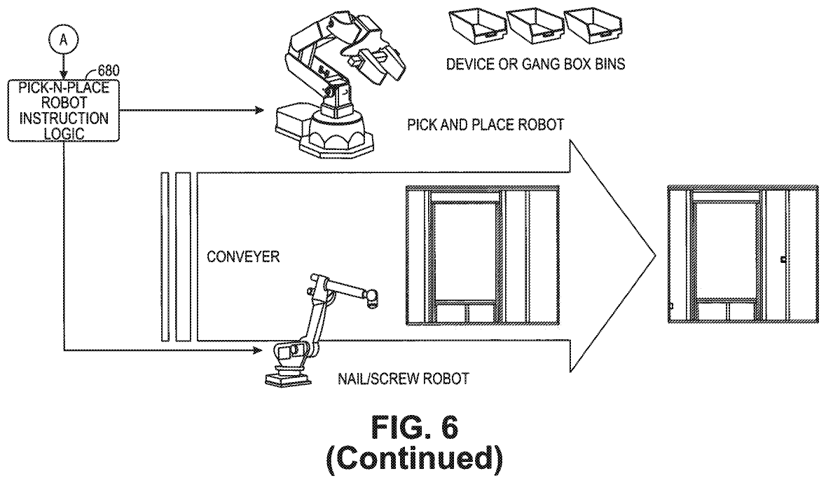

With reference to FIGS. 5G and 6, device location information, such as the electrical device location information 560, may be forwarded by logic 545, along with the BOM 550 and shop drawings 570, to logic 680 that controls a robotic arm to pick and place devices, such as the electrical devices, on a wall panel under construction in a manufacturing site or location, e.g., a wall panel on a conveyor belt passing by a robotic arm. While the embodiment illustrated in FIG. 6 depicts two robotic arms, one for picking and placing devices, and another for affixing the devices to the structural framing data members of a panel, it is understood that both functions may be performed by the same robotic device. According to a different embodiment, the device location information 560 may be forwarded by logic 545, along with the BOM 550 and shop drawings 570, to construction workers on a building site so that they can build the floors, walls, and ceilings of a building according to traditional on-site stick-by-stick framing and construction methods, knowing exactly where to locate the devices.

### Cost-Optimized Route for a Connecting Medium in a Three-Dimensional Model of a Building

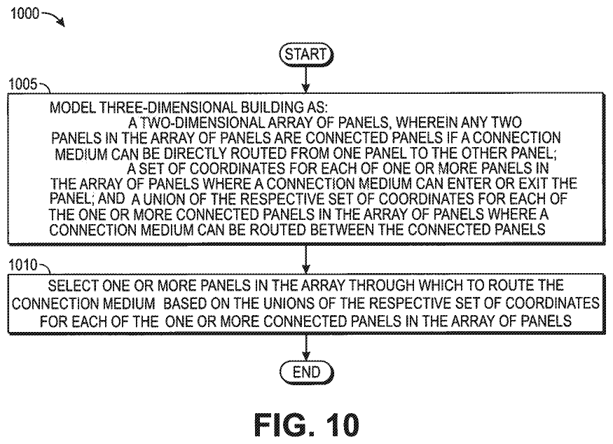

As discussed above, certain of the logic blocks as illustrated in FIG. 2, in accordance with embodiments of the invention, work together to provide a method for defining a route for a connecting medium within a three-dimensional building, such as the route for an electrical wire through a three-dimensional building, for example, a cost-optimized route, or a shortest-path route. With reference to FIG. 10, the method 1000 comprises logic 1005 for modeling the three-dimensional building as: a two-dimensional array of panels (wall, ceiling, floor, and open space panels), wherein any two panels in the array of panels are connected panels if a connecting medium can be directly routed from one panel to the other panel, a set of coordinates for each of one or more panels in the array of panels where a connecting medium can enter or exit the panel, and a union of the respective set of coordinates for each of the one or more connected panels in the array of panels where a connecting medium can be routed between the connected panels. Logic 1010 then selects one or more panels in the array through which to route the connecting medium based on the unions of the respective set of coordinates for each of the one or more connected panels in the array of panels.

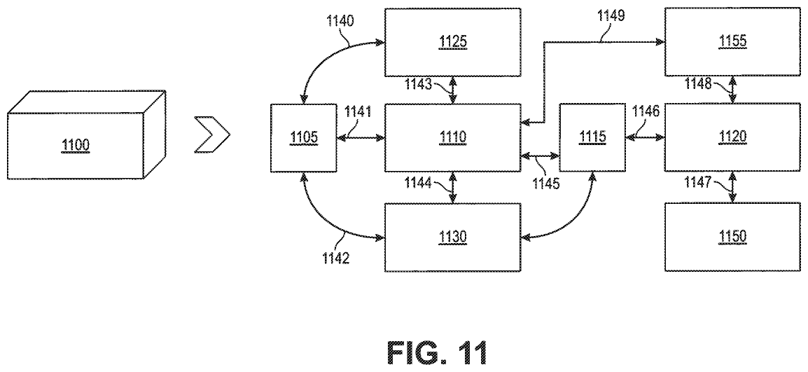

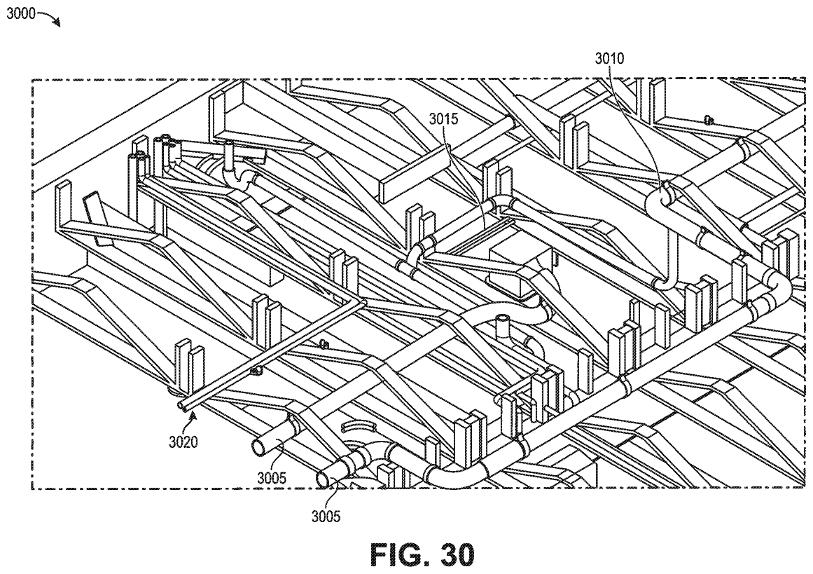

According to one embodiment 3000, with reference to FIG. 30, user rules may specify a prioritization scheme for selecting the one or more panels in the array through which to route a connecting medium based on, for example, the MEPF system involved, and/or the location of respective MEPF devices. For example, the user rules may require first selecting the one or more panels in the array through which to route a connecting medium based on the cost, or complexity of installing, the connecting medium for a specific type of MPEF system. For example, HVAC ducting 3005 occupies more space, requires a larger turn radius 3010, and may be more expensive for a given length, than water pipe 3015 or electrical wiring/conduit 3020, and so selecting the one or more panels in the array through which to route HVAC ducting is prioritized over selecting the one or more panels in the array through which to route a water pipe, or electrical wiring/conduit, where there is less cost, and more ease/flexibility in routing the water pipe or electrical wiring/conduit. Further details of this embodiment are discussed below with reference to FIGS. 11-23 and 31-34.

With reference to FIG. 11, the walls, ceiling, and floor of a three-dimensional building 1100, or a portion thereof, as well as any open space within or adjacent thereto, may be modeled as a two-dimensional array of panels, wherein any two adjacent panels in the array of panels are “connected panels” if a connecting medium can be directly routed from one panel to the other panel. For example, building 1100 has at least six panels, or sides, or faces: left (wall) panel 1105, top (ceiling) panel 1110, right (wall) panel 1115, bottom (floor) panel 1120, back (wall) panel 1125, and front (wall) panel 1130 in this simple embodiment.

In addition, the open space located within the six panels may itself be defined as one or more panels 1155 through which a connecting medium can be routed, for example, to and/or from one or more of the six panels. Likewise, open space outside and adjacent to an exterior surface of any one or more of the six panels may also be defined as one or more panels 1150 through which a connecting medium can be routed, for example, to and/or from one of the six panels. The one or more panels that define the open space within or outside the three-dimensional building or portion thereof may be space within a room or primary space of the building, or interstitial space located above ceilings, below floors, or between rooms or primary space, of a building, or outside space located above a roof, or next to an exterior surface of a wall or floor.

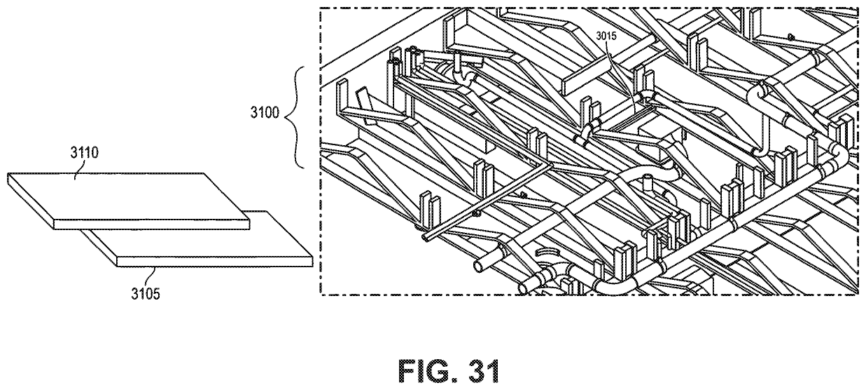

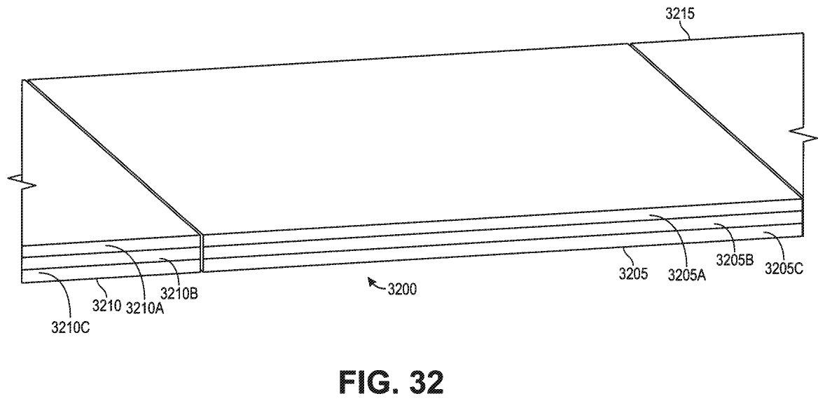

Further, according to an embodiment, physical panels or spaces in, of, or around, a building, such as a wall, floor, ceiling, interstitial space between floors, or outside space located adjacent an exterior surface of the building, may each be modeled not just as one panel, but as two or more panels stacked or sandwiched together in the same plane as multiple overlapping or partially overlapping layers, or positioned in the same plane as a single layer of multiple panels each abutting one or more other panels in the single layer. The plane may be oriented horizontally, vertically, or in a plane parallel, orthogonal, or at another angle with respect to the plane of an adjacent floor, wall, ceiling or roof. For example, with reference to FIG. 31, an interstitial space 3100 in a building model may be defined as two stacked panels 3105, 3110 through which HVAC ducting, water supply and drain lines, electrical conduit, etc., can be routed, for example, to and/or from panels 3105 and 3110. As another example, with reference to FIG. 32, a floor 3200 in a building model may be defined as abutting panels 3205, 3210, and 3215, and wherein each panel 3205, 3210, and 3215, is itself comprised of multiple abutting panels, for example, panel 3205 comprising panels 3205A, 3205B, and 3205C, and panel 3210 comprising panels 3210A, 3210B and 3210C, respectively.

The embodiment models all the panels as a two-dimensional array of panels, as illustrated in FIG. 11. Some pairs of adjacent or abutting panels are considered “connected panels” in the sense that a connecting medium for an MEPF system, such as an electrical wire for an electrical system can be routed directly from one panel to the other panel. The arrows 1140-1149 depict connections between two panels, in other words, the arrows depict connected panels. For example, left panel 1105 and top panel 1110 are connected panels as depicted by arrow 1141. Likewise, left panel 1105 and back panel 1125 are connected panels as depicted by arrow 1140, and left panel 1105 and front panel 1130 are connected panels as depicted by arrow 1142. Similarly, panel 1155 representing open space within building 1100 is connected to bottom panel 1120 and top panel 1110 as depicted by respective arrows 1148 and 1149, and panel 1150 representing open space below and adjacent to bottom panel 1120 is connected to bottom panel as depicted by arrow 1147.

Not every panel is necessarily connected to another panel, and not all adjacent panels are connected panels. For example, bottom panel 1120 is connected to right panel 1115 as depicted by arrow 1146, but even though bottom panel 1120 is adjacent to left panel 1105, back panel 1125 and front panel 1130, it is not a connected panel with any of those three panels as is indicated in FIG. 11 by the absence of an arrow between bottom panel 1120 and any one of left panel 1105, back panel 1125 and front panel 1130.

According to one embodiment, each panel is abstraction of a physical panel, or portion thereof, created by the structural framing data and optional panelization tool (e.g., CAD S/W 205, CAD S/W 405), or an abstraction of an area of open space, or portion thereof, within, or outside, the three-dimensional building 1100. The panel abstraction, referred to herein as a YawPanel, is a route friendly abstraction of a physical panel, or open space panel, or a portion thereof, and all connecting medium routing happens within, or is mapped through, one or more panels according to embodiments of the invention, as described further below. Two panels, in particular, two YawPanels, are connected panels (from the perspective of routing connecting media such as electrical wires or cables, or plumbing supply or drain pipe) if or when a connecting medium can go from one panel to another panel, that is, when a connecting medium can exit one panel and enter another panel.

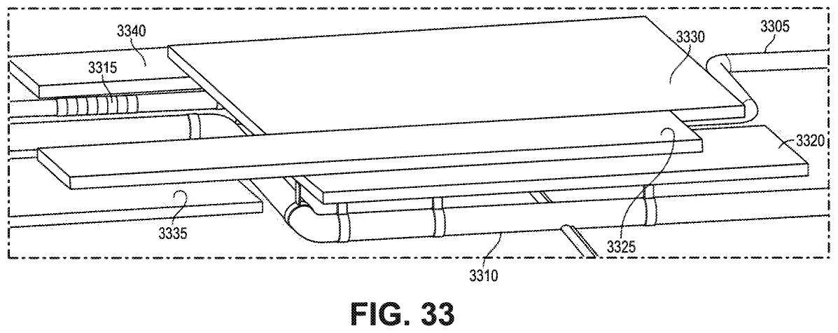

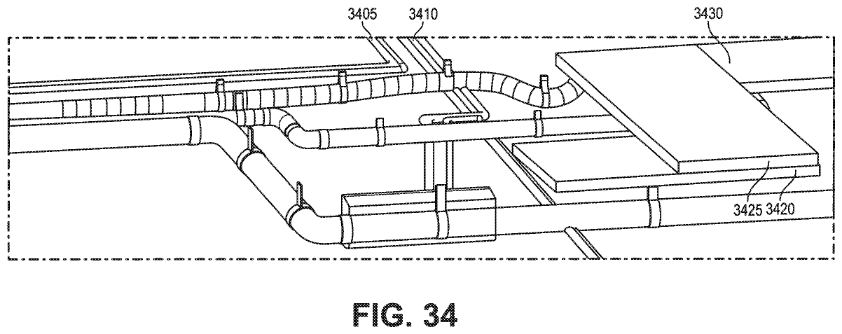

According to an embodiment, different arrangements or groupings of YawPanels may be used to provide the route friendly abstraction of one or more physical panels, or open space panels, or a portion thereof, for a specific type of MEPF connecting media that is to be routed within, or mapped through, the YawPanels. For example, with reference to FIG. 33 and FIG. 34, after a first MEPF system connecting media is routed (see, e.g., pipes 3305, 3310 and 3315), an arrangement or grouping of YawPanels 3320-3340 is used to provide a route friendly abstraction of open spaces for routing a different specific type of MEPF connecting media, e.g., electrical conduit (3405, 3410) through the open space surrounding the MEPF connecting media 3305, 3310, 3315. Thereafter, yet another arrangement or grouping of YawPanels 3420, 3425, 3430 may be used to provide a route friendly abstraction of open spaces for routing yet another different specific type of MEPF connecting media, e.g., fire suppression supply lines (not shown).

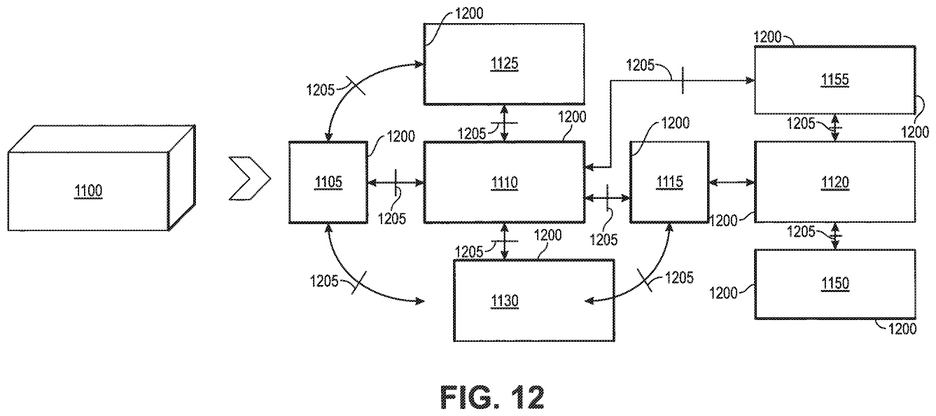

According to the embodiments, a set of coordinates, referred to herein as “panel coordinates”, or a “YawPanelEdge”, may be generated for each of one or more panels in the array of panels to identify an “edge” where a connecting medium such as an electrical wire can enter or exit the panel. See, for example, the heavy black lines 1200 along one or more edges of the panels in FIG. 12, which depict the edges on the side of panels where a connecting medium can enter or exit the panel.

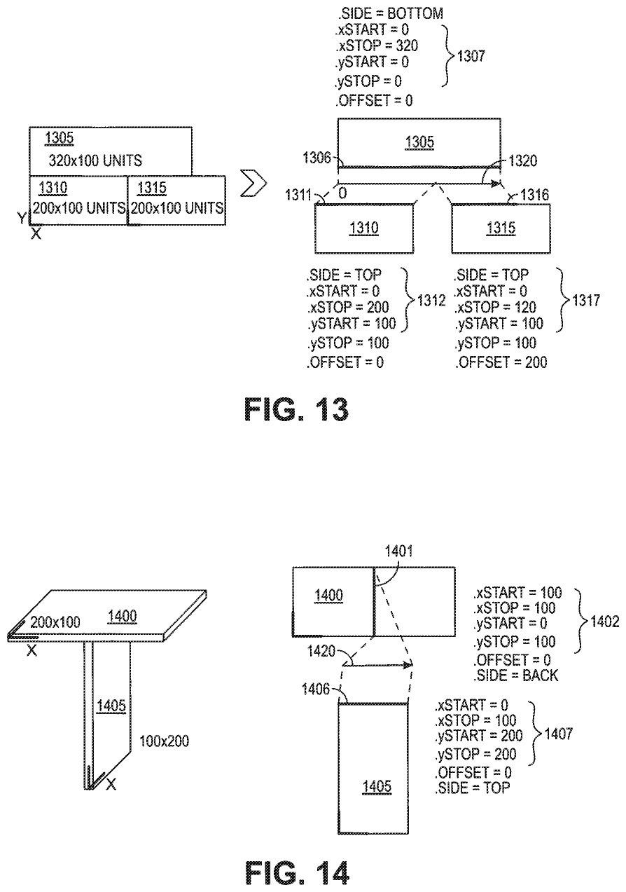

FIG. 13 illustrates an array of panels 1305, 1310 and 1315, each with a set of coordinates identifying locations (areas) at which a connecting medium can enter or exit the panel, referred to herein as “side edges” of the panel. Side edges exist on the boundary of a panel and are of side type BOTTOM, RIGHT, LEFT, or TOP. In one embodiment, side edges are LINEAR objects. A LINEAR object identifies one row of a column of cells that is abutted to cells of another panel. A panel can have several non-overlapping side edges of the same side type. In FIG. 13, there are three panels 1305, 1310 and 1315. Panel 1305 has a length of 320 units (the unit of measure is not relevant in this example) along the X axis, and a width or height of 100 units along the Y axis. Panels 1310 and 1315 each have a length of 200 units along the X axis, and a width or height of 100 units along the Y axis.

YawPanels 1305 and 1310 are connected panels, as depicted by the heavy black lines 1306 and 1311, and panels 1305 and 1315 are connected panels, as depicted by the heavy black lines 1306 and 1316. The example in FIG. 13 only highlights horizontal side edges by which two panels are connected. It is appreciated that similarly, two panels may be connected by vertical side edges, or by vertical and/or horizontal edges, depending on the positions of the panels with respect to each other. The panel coordinates, or YawPanelEdge coordinates 1307, at which a connecting medium can enter or exit panel 1305 are listed in FIG. 13 with reference to an origin of zero (0) on an X and Y axes, located in the lower left corner of the panel. In particular, the coordinates extend from X=0 to X=320 units, and from Y=0 to Y=0 (this being a horizontal bottom side edge, and not a vertical side edge). The offset for the coordinates along the X axis for this panel in the array of panels is zero. Similarly, the coordinates 1312 and 1317 for respective panels 1310 and 1315 are expressed as follows. The coordinates for panel 1310 extend from X=0 to X=200 units, and from Y=100 to Y=100 (this being a horizontal top side edge, and not a vertical side edge), with an offset of zero for the coordinates along the X axis for this panel in the array of panels. The coordinates for panel 1315 extend from X=0 to X=120 units, and from Y=100 to Y=100, from an offset of 200 for the coordinates along the X axis for this panel in the array of panels. Note the ending X coordinate (.xStop)=120, indicating the side edge of the panel at which a connecting medium can enter or exit the panel extends only along the first 120 units of length along the top side edge of the panel, and not the entire length of the top side edge, compared to panel 1310, due to panel 1315 extending to the right beyond the right vertical side edge of panel 1305. Further, note the offset (.offset) for the beginning of the coordinates=200.

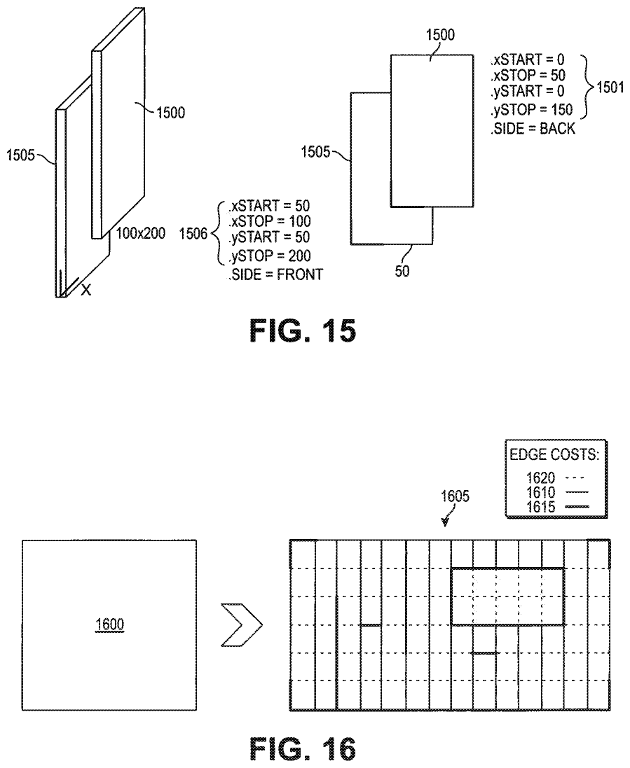

The example in FIGS. 12 and 13 demonstrate the case where the set of coordinates, or locations, at which a connecting medium can enter or exit a panel, apply to “side edges” of the panel. However, “front edges” and “back edges” are also possible, as depicted in FIG. 14, and “area edges” are also possible, as depicted in FIG. 15. In one embodiment, area edges are AREA objects. An AREA object identifies an AREA of cells that is abutted to a similar or overlapping area of cells on another abutted panel. With reference to FIG. 14, even though YawPanels are idealized two-dimensional objects, they can be connected in three-dimensional fashion. “Front edges” and “back edges” specify such connections between two panels. Front and back side yaw panel edges can be linear (e.g., to form a “T”) or area (parallel planes) objects. In the example illustrated in FIG. 14, panel 1400 has a back side edge 1401 and panel 1405 has a top side edge 1406, and the top side edge 1406 of panel 1405 is connected to the back side edge 1401 of panel 1400. Panel 1400 has a length of 200 units along the X axis, and a width or height of 100 units along the Y axis, while panel 1405 has a length of 100 units along the X axis, and a height of 200 units along the Y axis. The top side edge of panel 1405 abuts the back side edge of panel 1400, creating a line where connecting medium routes can exit one panel and enter the other panel. The panel coordinates, or YawPanelEdge coordinates 1402, at which a connecting medium can enter or exit the back side edge of panel 1400 extends from X=100 to X=100 units, and from Y=0 to Y=100. The YawPanelEdge coordinates 1407, at which a connecting medium can enter or exit the top side edge 1406 of panel 1405 extend from X=0 to X=100 units, and from Y=200 to Y=200.

With reference to FIG. 15, “area edges” are illustrated. Panels 1500 and 1505 each has a length of 200 units along the Y axis, and a width of 100 units along the X axis. Panels 1500 and 1505 are abutted front to back, creating an area of overlap where connecting medium routes can exit one panel and enter the other panel. These areas of overlap are connections that are modeled as “area edges”. In this particular case, the front edge of panel 1505 is connected to the back edge of panel 1500. The panel coordinates, or YawPanelEdge coordinates 1506, at which a connecting medium can enter or exit the front area edge of panel 1505 are listed in FIG. 15 with reference to an origin of zero (0) on an X and Y axes, located in the lower left corner of the panel. In particular, the coordinates extend from X=0 to X=100 units, and from Y=50 to Y=200. The YawPanelEdge coordinates 1501, at which a connecting medium can enter or exit the back area edge of panel 1500 extend from X=0 to X=50 units, and from Y=0 to Y=150.

With reference to FIG. 12, given the panel coordinates for a panel at which a connecting medium can enter or exit the panel (a “YawPanelEdge”), the union or combination of those coordinates with the coordinates of an adjacent, abutting, panel at which the connecting medium can enter or exit the adjacent panel defines a “YawEdge” where the connecting medium can be routed between the two adjacent, abutting panels. Embodiments of the invention select one or more panels in the array of panels through which to route a connecting medium based on these unions of the set of coordinates for each of the one or more connected panels in the array of panels. The lines 1205 in FIG. 12 depict the union of the panel coordinates (YawPanelEdges) for abutting panels that define where a connecting medium can be routed between the panels. Likewise line 1320 in FIG. 13 and line 1420 in FIG. 14 depicts this union. In FIG. 15, the union (YawEdge area) is inferred by the area of overlap between the abutting panels.

With reference to FIG. 15, according to embodiments, each panel in the 2D array of panels is itself an abstraction of its own two-dimensional array (a YawPanel) for purposes of determining a cost-optimized path or route for a connecting medium entering and/or exiting the panel, or connecting to MEPF device located near, in, or on the panel. The embodiments model each panel in the two-dimensional array of panels as a two-dimensional array, or grid, of quadrilateral cells, assign a cost to each cell in the array of cells for the panel, and calculate a route for the connecting medium through each panel based on the assigned costs of the cells in the array of cells for the panel.

According to an embodiment, the two dimensional array of quadrilateral cells is modeled to align with a structural design of a corresponding physical panel in the three-dimensional building, or with the interruptions or blockages that may exist in an panel corresponding to an area of open space, for example, as may occur when structural members such as rafters or beams, or MEPF components, such as power supplies, compressors, electrical or mechanical manifolds, etc., or connecting media such as HVAC ducting or water pipes, are located within or pass through the area of open space defined by the panel. Further according to the embodiments, one or more panels in the array of panels is selected through which to route a connecting medium based not only on the unions of the set of coordinates for each of the one or more connected panels in the array of panels but also based on the defined route for the connecting medium through each panel based on the assigned costs of the cells in the array of cells for the panel.

In one embodiment, a cost is assigned to each side of each cell in the array of cells for the panel. In such an embodiment, assigning the cost to each cell in the array of cells involves assigning the cost to each cell based on the assigned cost to each side of the cell. For example, the assigned cost to each cell may the sum of the assigned cost to each side of the cell, or the sum or the assigned cost to one of the two pair of opposing sides of the cell.

With reference to FIG. 16, a data model for a YawPanel is illustrated. A YawPanel is rectangular, according to embodiments of the invention. A physical or open space panel 1600 is abstracted into a two-dimensional array of cells 1605. A minimal number of rows and columns are used to define the cells, sufficient to define the corresponding blockages from studs, beams, plates, windows, doors, MEPF equipment, MEPF connecting media, etc., within the two-dimensional array of cells. Row height and/or column width may vary from panel to panel, and/or from row to row or column to column within a panel, but is consistent within each row and column of a given panel. Blockages are represented by cell edges and are assigned a cost 1610 that can vary depending on the blockage. For example, studs and beams are modeled as edge costs and can vary for each cell, depending on cell location, and the thickness of such studs and beams. Likewise, openings or blockages presented by windows and doors or other restricted areas (e.g., the header above a window or door) are modeled as cell blockages, and no transition or route through such blockage is allowed. Similarly, blockages presented by MEPF equipment or components, or connecting media there between, are modeled as cell blockages. Essentially, the cost 1615 assigned to such cells is prohibitively high, or infinite. Conversely, holes or openings from one cell to another cell are modeled at a cost 1620 of zero. Essentially, holes are modeled by removing the edge or side cost at individual cells.

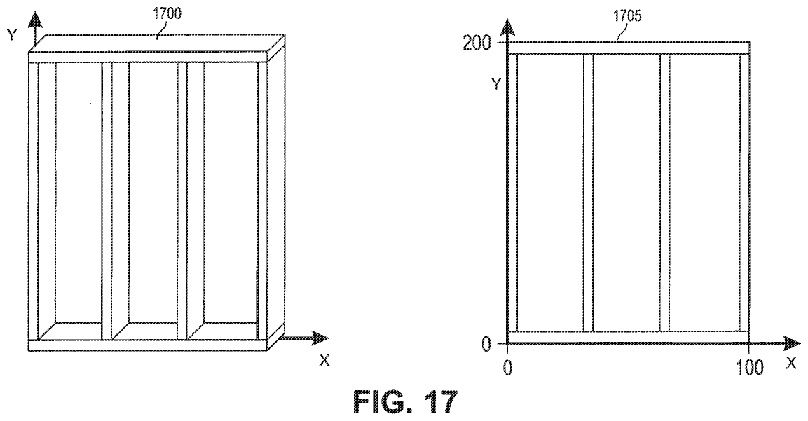

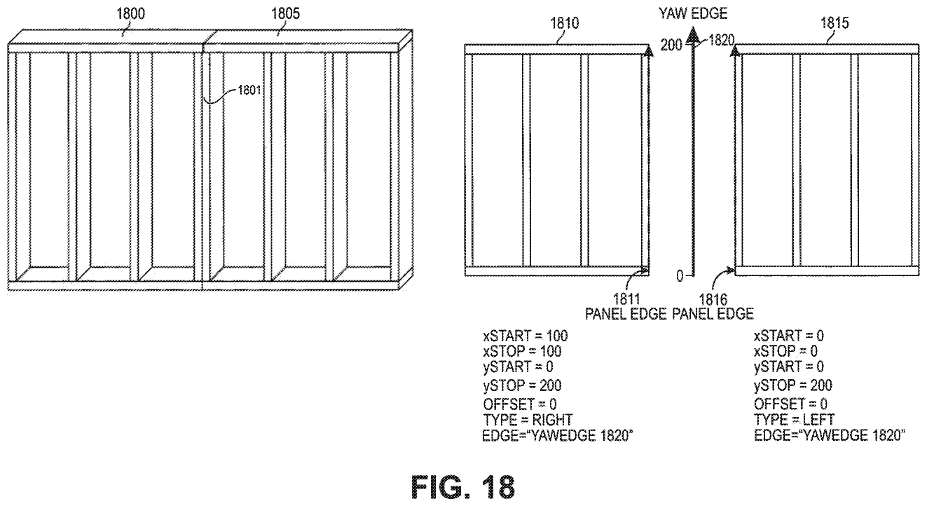

FIG. 17 illustrates a data model for a YawPanel in which a physical panel 1700, comprised of, for example, studs, beams, headers, plates, and openings that are actually three dimensional, is abstracted into a two-dimensional array of cells (YawPanel) 1705. FIG. 18 illustrates two abutting physical panels 1800 and 1805 abstracted into two abutting YawPanels 1810 and 1815. Just as the two physical panels 1800 and 1805 are physically connected along abutting edges 1801, the YawPanels 1810 and 1815 are side by side “connected panels” by virtue of the right side edge (YawPanelEdge) 1811 of YawPanel 1810 abutting left side edge (YawPanelEdge) 1816 of YawPanel 1815. The union of YawPanelEdge 1811 and 1816 is represented by YawEdge 1820, and consists of the respective coordinates of the right side edge of YawPanel 1810 and the left side edge of YawPanel 1815. In the example illustrated in FIG. 18, the coordinates for the connection at the right side edge of YawPanel 1810 are X=100 to X=100, and Y=0 to Y=200, and the coordinates for the connection at the left side edge of YawPanel 1815 are X=0 to X=0, and Y=0 to Y=200. Generally speaking, a panel can only have a left connection at xstart=xstop=0 and a right side edge connection at xstart=xstop=xdim, where xdim is the length of the panel along the X axis.

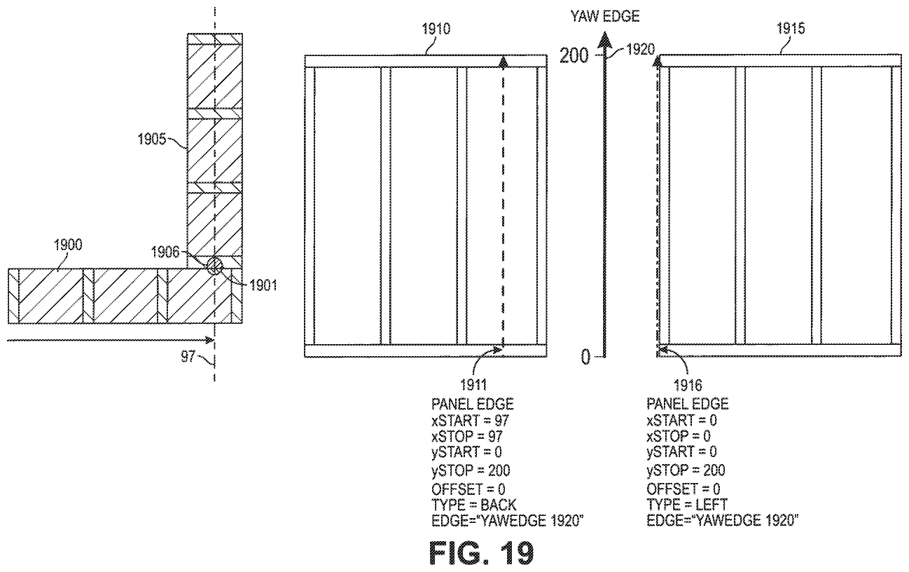

FIG. 19 illustrates two physical panels 1900 and 1905 abutting at the back 1901 of panel 1900 and the left side edge 1906 of panel 1905, abstracted into two abutting YawPanels 1910 and 1915. Just as the two physical panels 1900 and 1905 are physically connected along the back side 1901 of panel 1900 abutting next to the edge 1906 of panel 1905, the YawPanels 1910 and 1915 are side to back “connected panels” by virtue of the back edge (YawPanelEdge) 1911 of YawPanel 1910 abutting the left side edge (YawPanelEdge) 1916 of YawPanel 1915. The union of YawPanelEdge 1911 and 1916 is represented by YawEdge 1920, and consists of the respective coordinates of the back edge of YawPanel 1910 and the left side edge of YawPanel 1915. In the example illustrated in FIG. 19, the coordinates for the connection at the back edge of YawPanel 1910 are X=97 to X=97, and Y=0 to Y=200, and the coordinates for the connection at the left side edge of YawPanel 1915 are X=0 to X=0, and Y=0 to Y=200.

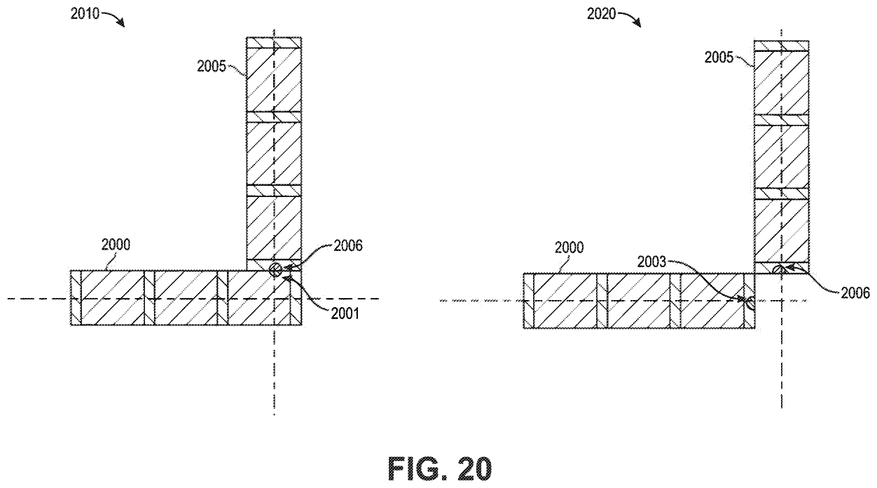

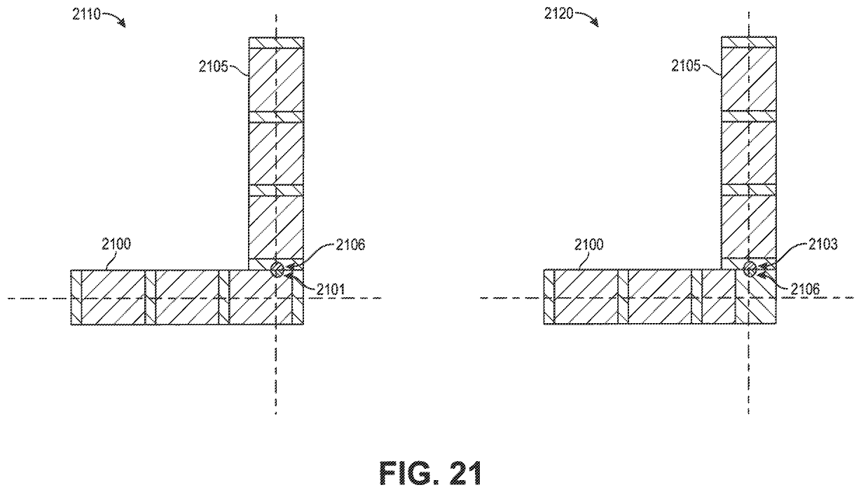

FIG. 20 illustrates vertical orthogonal physical panels 2000 and 2005 abutting side to back at 2010, where only one stud needs to be drilled, versus abutting side to side at 2020, where two studs needs to be drilled, to accommodate a wire routed from one panel to the other. In the side to back situation 2010, a wire would be routed to the left side 2006 of panel 2005 and the back side 2001 of panel 2000. In the side to side situation 2020, a wire would be routed from the left side 2006 of panel 2005 to the right side 2003 of panel 2000.

FIG. 21 further illustrates vertical orthogonal physical panels 2100 and 2105 abutting side to back at 2110, where the back YawPanelEdge 2101 of panel 2100 is between studs, so a wire route from panel 2100 to 2105 is possible, where only one stud needs to be drilled, versus abutting side to side at 2120, where the back YawPanelEdge 2016 is on two studs of panel 2100 that need to be drilled, in addition to the stud at the left side edge 2103 of panel 2015 that needs to be drilled, to accommodate a wire routed from one panel to the other. In the side to back situation 2110, a wire would be routed to the left side 2106 of panel 2105 and the back side 2101 of panel 2100. In the side to back situation 2020, the route for a wire from the back side 2106 of panel 2100 to the left side 2103 of panel 2105 is effectively blocked, as two holes would need to be drilled at orthogonal angles to each other, and somehow a wire routed through the resulting corner, which is too costly in terms of installing the wire to be routed between panels 2100 and 2105.

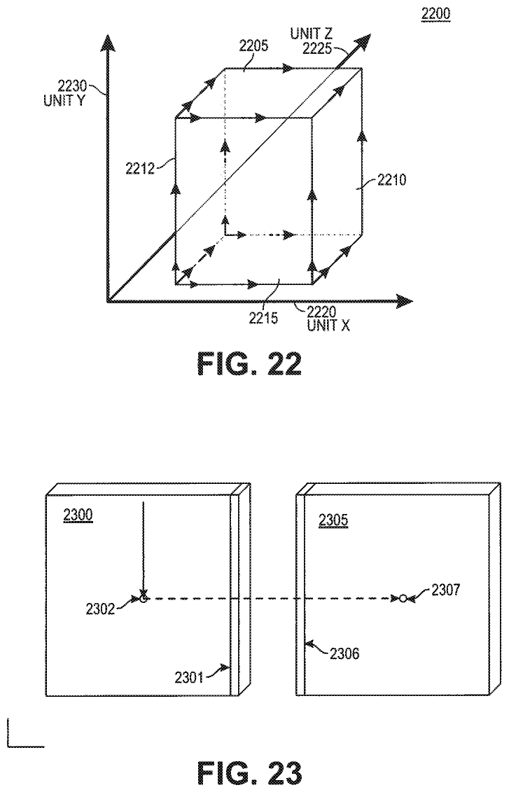

FIG. 22 illustrates at 2200 the local origin of YawPanels, according to embodiments of the invention. Recall from above the definition of a YawEdge as the union or combination of coordinates for one panel with the coordinates of an adjacent, abutting, panel at which a connecting medium can be routed between the two adjacent, abutting panels. YawEdges have a direction and the direction of connected panel edges match. That is, when walking a YawEdge, by increasing its coordinate, the corresponding points on the connected panels should have one coordinate increase (the other is constant). As long as the direction of all unit X, or Y, or Z axis arrows is the same this constraint is met. Once the direction is set, the local origin of all panels is set.

If the panels are aligned with a unit coordinate system such as illustrated in FIG. 22, then using UnitX axis 2220 and UnitZ axis 2225 as the direction for the CeilingPanel 2205 local coordinates, using UnitX axis 2220 and UnitY axis 2230 for the direction of panels aligned with the UnitX axis 2220 (e.g., FrontPanel 2215), and choosing UnitZ axis 2225 and UnitY axis 2230 for the panels aligned with the UnitZ axis 2225 (e.g., RightPanel 2210) accomplish that. In the example illustrated in FIG. 22, the right side of FrontPanel 2215 is connected to the left side of RightPanel 2210, and the left side of the FrontPanel 2215 is connected to the left side of the LeftPanel 2212.

A cost model for optimizing cost associated with routing a connecting medium from one cell to another cell takes into consideration such costs as: the cost of the connecting medium itself, whether electrical wire or cabling, water pipes, HVAC ducting, etc., the cost of turning a corner with the cable, pipe, or ducting, the cost of existing holes, the cost of drilling new holes, savings for using or re-using existing holes for different electrical, plumbing, or HVAC networks, the costs of routing connecting media through an area (e.g., some areas can be tagged as less desirable, i.e., more costly, than other areas). Embodiments of the invention find the lowest-cost route to all cells and saves the route information for the path to relevant cells, and connect N MEPF devices (as a cheapest sequence, or cheapest electrical network) using N-1 routes.

FIG. 23 illustrates one implementation of a cost model used for optimizing cost associated with routing a connecting medium from one cell (YawCell 2300) to another cell (YawCell 2305) in the array of two-dimensional cells of a YawPanel in accordance with embodiments of the invention. Routing goes from the center 2302 of cell 2300 to the center 2307 of the other cell 2305. Within a cell there are no obstructions, or blockages, and no associated cost(s). At the edges of a cell, there may be a blockage, either a hard blockage (through which a connecting medium cannot be routed, represented, for example, by a prohibitive or infinite cost, or by removing a cell to cell connection), or a soft blockage (through which a connecting medium can be routed, but represented at a cost that can vary depending on the type of blockage and/or the requirements/costs to route the connecting medium around the soft blockage). These blockages can occur at top, bottom, left, right, front or back of a cell. For example, cell 2300 has a soft blockage 2301 that represents a stud at the right edge of the cell, and cell 2305 has a soft blockage 2306 that represents a stud at the left edge of the cell. The total cost to route a connecting medium from cell 2300 to cell 2305 is the sum of the costs of the soft blockages 2301 and 2305.

In general, assuming the total cost to route a connecting medium to a first cell is known, the cost to route the connecting medium to an adjacent, second cell to the right of the first cell is the sum of: a corner cost if the route for the connecting medium to the first cell comes from the top or bottom of the cell (and does not come from the left side of the first cell); the connecting medium cost (for the connecting medium to travel half the width of the first cell from the left edge to the center of the cell), the edge cost of exiting the first cell (for the connecting medium to travel half the width of the first cell, from the center of the cell to the right edge of the cell), the edge cost of entering the second cell (for the connecting medium to travel half the width of the second cell from the left edge to the center of the cell), and the body cost of the second cell.

Embodiments of the invention route a connection according to the following costs:

1. Aggregated connecting medium cost: Embodiments model the material and labor cost of the connecting medium (e.g., based on cost of a selected connecting medium (obtained from a connecting media library) with a 35% overhead cost (per RSMeans) (obtained from a cost library));

2. Corner cost: Embodiments model extra connecting medium and increased installation effort, mainly used to ensure the minimization of corners (e.g., fixed cost per type of cable (cost library));

3. Edge cost: Embodiments model the labor cost of drilling a hole through a stud, beam, header plate, and the like (e.g., cost per inch drilling depth (cost library));

4. Body cost: Adds a (micro) cost to identify less desirable route areas (e.g., a vertical route through a cell neighboring a stud is preferred above a cell not neighboring a stud, as the former allows the connecting medium to be affixed to the stud);

5. Re-use discount: A discount can be specified for the edge cost and connecting medium cost if a (partial) path is re-used. The discount for re-using holes is significant.

According to embodiments of the invention, MEPF optimization can be performed, in which a complete system, such as an electrical circuit, or a plumbing run, is globally optimized. Embodiments of the invention may decide:

1. Which of all eligible MEPF to connect to MEPF equipment or components, e.g., which of all eligible electrical devices to connect to the load center, or which of all eligible plumbing fixtures to connection to a water supply lines or drain lines;

2. The order in which to connect various MEPF components, from among the different MEPF systems, and within a particular MEPF system. For example, the order in which to connect the mechanical, electrical, plumbing, and fire suppression systems, and the order in which to connect components within each system such as when to connection mechanical components in the mechanical system, electrical switches in each electrical circuit, and if more than two switches, which ones to will be single pole, three-way and which ones double pole three-way, plumbing fixtures/components in the plumbing system, and sprinkler heads/fire suppression components in the fire suppressing system; and

3. What device-to-device connections to use to connect a set of devices.

Optimization may be based on total routing cost, not just connecting medium length or distance, in which embodiments:

1. Understand costs of adding corners internally and externally (between panels);

2. Understand costs of traversing beams and studs; and

3. Understand savings of using pre-drilled holes and re-using identified new holes.

### Detailed Route for a Connecting Medium in a Three-Dimensional Model of a Building

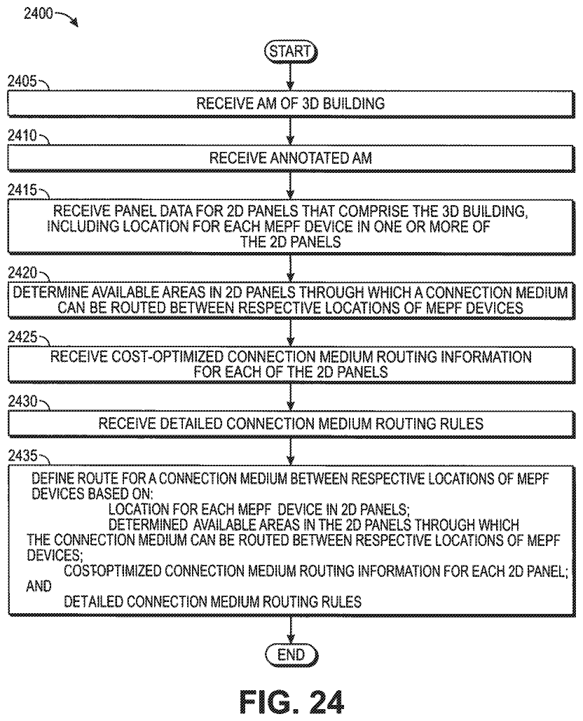

As discussed above, certain of the logic blocks as illustrated in FIG. 2, in accordance with embodiments of the invention, work together to provide a method for defining a detailed route for a connecting medium between MEPF devices in a plan for a three-dimensional (3D) building. With reference to FIG. 24, the method 2400 comprises logic 2405 for receiving an architectural model (AM) of the 3D building, and/or logic 2410 for receiving an annotated AM with structural design information, and MEPF design information. Logic 2415 receives structural framing data for a plurality of two-dimensional (2D) panels that comprise the 3D building based on the annotated AM, the structural framing data comprising a location for each of a plurality of MEPF devices near, in, or on one or more of the plurality of 2D panels. Logic 2420 then determines available areas in one or more of the plurality of 2D panels through which a connecting medium can be routed between respective locations of two or more of the plurality of MEPF devices. Logic 2425 receives the cost-optimized connecting medium routing information for each of the plurality of 2D panels. Logic 2430 receives detailed connecting medium routing rules. Finally, logic 2435 defines a route for a connecting medium between respective locations of two or more of the plurality of MEPF devices in one or more of the plurality of 2D panels based on one or more of: the location for each of a plurality of MEPF devices in one or more of the plurality of 2D panels; the determined available areas in one or more of the plurality of 2D panels through which the connecting medium can be routed between respective locations of two or more of the plurality of MEPF devices; the cost-optimized connecting medium routing information for each of the plurality of 2D panels; and the detailed connecting medium routing rules.

With reference to the functional block diagram in FIG. 4A, an embodiment of the invention 400 includes MEPF details logic 440 which includes connecting medium routing logic 460 to specify a connecting medium route between MEPF devices in an architectural model for a three-dimensional (3D) building, and means for routing and affixing the connecting media to, panels, or beams and studs within the panels using appropriate affixing means, and exactly where on, or in, the panels, or on the beams or studs, to affix or otherwise support the connecting media. In particular, embodiments of the invention provide a detailed three-dimensional routing of interconnection systems based on three-dimensional spaces and a determination of custom paths or routes for connecting media. As discussed further below, embodiments provide an automated process of routing connecting media to manufacturable and installable details, including automatically generating drill holes, for example, for water pipes or electrical cable runs that can be sent to a CNC machine for precise drilling, and further generating an accurate bill of materials that includes all components of MEPF systems, such as, for example, water supply and drain lines, plumbing fixtures, straps, braces, hangers, electrical wiring, electrical devices, cables, staples, zip ties, end caps, and cable stackers, etc. Shop drawings too are generated automatically and accurately provide seamless manufacturing of panels that contain or to which MEPF components and connecting media, such as Wire-In-Wall or Plumbing-In-Wall, or Wire-on-Wall or Plumbing-on-Wall panels. Finally, installation drawings 480 are generated to make site installation of MEPF connecting media with clear instructions. Different embodiments provide a manual process of routing connecting media, including automatically generating instructions for drill holes, for example, for water supply and drain lines that can be sent to a plumber on-site, and/or electrical cable runs that can be sent to an electrician on-site, for precise drilling, and further generating an accurate bill of materials that includes all components of plumbing and associated fixtures, and electrical wiring, electrical devices, cables, staples, zip ties, end caps, and cable stackers. Shop drawings too are generated automatically and accurately provide the information needed to construct at the building site the floors, ceilings, and walls of the building, and provide for the installation of MEPF components such as plumbing fixtures and electrical devices. Finally, installation drawings are generated to make site installation of MEPF connecting media with clear instructions.

Embodiment 400 receive as input an architectural model 420 for a building project comprising one or more buildings. The architectural model (AM) may be created with building information modeling (BIM) software 415. In the illustrated embodiment, the BIM software does not include MEPF design information. Such information is input as part of the MEPF Model 421. BIM plug-in software 425 receives the MEPF Model 421 as input and augments the AM to include this information. Likewise, structural design information is not present in the AM 420. Computer aided design (CAD) structural framing data and optional panelization software 405 generates an IFC data model 410 of structural framing data and optional panelization information. In one embodiment, the IFC data model 410 of the structural framing data and optional panelization data is not compatible with the BIM software and corresponding database, so the IFC data model 410 is converted into a structural frame model 411 that is compatible with the BIM software and corresponding database, and then added to the AM via the BIM plug-in software 425. In another embodiment, the IFC data model is compatible with the BIM software and database and so is input or incorporated directly into the database by BIM plug-in software 425 to augment the AM to include the structural design information.

The BIM plug-in software 425 receives the architectural model 420, the structural framing data and optional panelization information in structural frame model 411, and the MEPF design details in MEPF Model 421, and generates data objects 435, such as data objects for detail route rules, connecting medium library objects and MEPF device categories (discussed above). These data objects are input to and used by the MEPF details logic 440, in particular, the connecting medium route logic 460, to route connecting media between the MEPF devices located within the panels.

Examples of detail route rules for an MEPF system, such as the electrical system include:

1. Cable Supports
maxSeparation: maximum allowed separation between supports;
maxFromDevice: maximum allowed support distance from device; and
minRollUpDiameter: minimum diameter of roll-ups.

2. Drills
preDrillDiameter: diameter of pre-drilled holes;
preDrillHeight: height of pre-drilled holes from bottom;
diameter: typical diameter of custom drill holes for electrical cables;
maxStudThickness: maximum thickness of stud that can be drilled; and
maxStudPack: maximum number of studs in a pack or group that can be drilled.

Examples of connecting medium library objects for an MEPF system, such as the electrical system, include:

1. Cables

2. Cable supports

3. Zip ties

4. End caps

5. Cable stackers

Similar detail route rules and connecting medium library objects are contemplated for other MEPF systems, such as the plumbing system, HVAC system, fire suppression system, data network system, etc.

Embodiments of the invention receive at MEPF details logic block 440 the data objects 435, including structural framing data the structural frame model 411, and further from one or more libraries, user control rules 436 and code (e.g., NEC) rules 437. User control rules are control parameters that a user can input to control the connecting medium route logic 460 in terms of where to route connecting media, such as electrical cables or water supply or drain pipes. For example, user rules might include allowable locations for drilling holes in beams or studs 485, and the maximum diameter and length of any such holes.

A known product number (KPN) database 430 provides corresponding part numbers for each object 435, whether the KPN for a MEPF device 432, or the KPN for connecting medium 433, and costs data for each device or connecting medium, to the MEPF details logic 440.

Connecting medium route logic 460 generates the specific routes for MEPF connecting media between MEPF devices, such as specific routes for electrical cables between electrical devices, based on the user rules and code rules, and outputs the specific connecting medium route details, such as electrical wiring route details, 465. This information, in turn, is provided to CAD structural framing data and optional panelization software 405, wherein a CAD user can modify the Structural frame IFC data 410 to take into consideration new details regarding the actual placement, or location, of the MEPF devices, and connecting media routed there between. The Structural frame IFC data 410, in turn, may be converted to structural frame model 411 data and added to the BIM by BIM plug-in software 425, which updates the connecting medium detail and drilling model 470 for the BIM accordingly.

With reference to FIG. 25A, one embodiment 2500 for connecting medium routing logic 460 is described as follows, referring to the electrical system as one example of routing connecting media between MEPF devices. Similar embodiments are contemplated for plumbing supply and drain line routing logic, or other MEPF system routing logic, such as HVAC ducting routing logic, or fire suppression supply line routing logic. The process in the example embodiment 2500 receives structural framing data model 511, location information for pre-drilling holes 2505, electrical device location information 2510, cost-optimized approximate cable routing information 2525 (generated according to the embodiments described above), and detail routing rules 2540. Logic 2515 identifies individual structural frame blockages, e.g., structural framing members of panels, such as beams, studs, plates, where an electrical cable cannot be routed, and merges adjacent structural frame blockages and electrical device placements for each panel, as depicted at 2530 (and with reference to the process described above with reference to FIG. 5D, in which respective abutting vertical studs 517, 518, 519, and 527 are merged as a structural frame blockage as a single structural frame blockage 516 for the purpose of locating an MEPF device). Some or all of this information may previously have been saved at logic 505 and provided as input to logic 2515

With reference to FIGS. 5A, 5E and 25A, logic 2520 identifies additional areas, such as opening 522 (windows, doors), and restricted areas 523, 524 where an electrical cable cannot, should not, or preferably should not, be routed, such as through or under or over a window, and merges adjacent areas as single area blockage. Area blockages, in turn, as the case may be, are merged with the adjacent merged structural frame blockages. For example, with reference to FIG. 5E, structural frame blockages and area blockage are merged into one blockage 521. A MEPF connecting medium such as an electrical cable will not be routed through a blockage 521. Embodiments of the invention group, or geometrically merge, the structural frame blockages and area blockages to represent the blockages as a single blockage 521 for the purpose of routing a connecting medium, such as an electrical cable, as depicted at 2535.

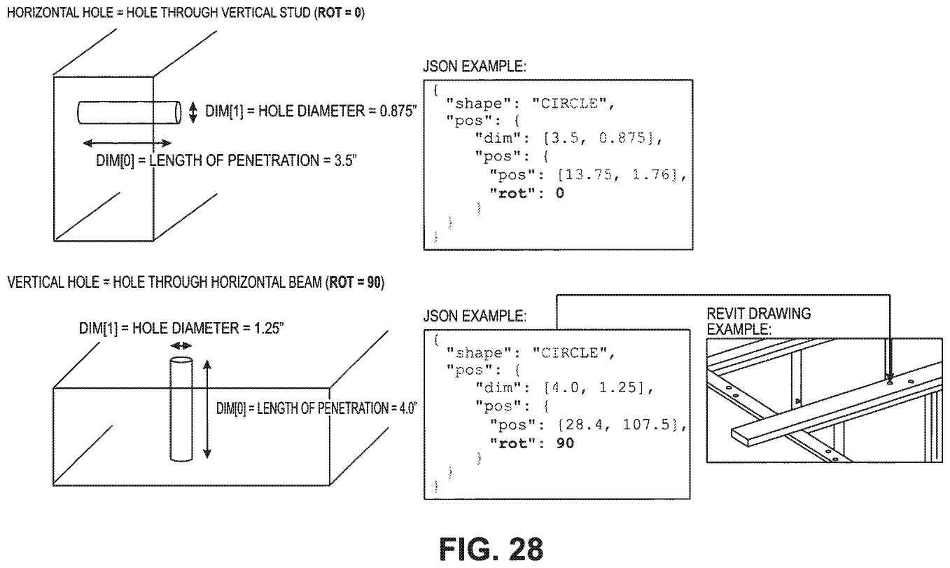

Logic 2550 then determines, based on the above inputs, a detailed route for each electrical cable, and outputs one or more of: 1) a cable and cable support Bill of Materials 2556, with reference to FIG. 25B, 2) shop drawings 2560/2561, with reference to FIG. 25C, which shows exact cable routes and even where to loop or roll-up excess cables that will be pulled through an exit of the panel to connect to an electrical device in another panel once the panels are assembled, for example, on the building site, 3) an installation drawing for each individual electrical cable 2565/2566, with reference to FIG. 25D, and 4) custom drilling instructions 2570 for a CNC machine, which, in turn, performs automatic drilling on studs with logic 2575 to provide the holes needed to route the electrical cables. FIG. 28 illustrates custom drilling instruction for CNC, as may be output at logic 2570.

Similarly, embodiments of the invention determine, based on the above inputs, a detailed route for each connecting medium, and outputs one or more of: 1) a connecting medium and a connecting medium support Bill of Materials similar to the BoM 2556 for electrical cable support, but for other types of connecting media, 2) shop drawings in keeping with 2560/2561 for other of the MEPF system, which shows exact connecting medium routes and even where to store connecting medium, e.g., water supply or drain lines, that will be pulled through an exit of the panel to connect to an plumbing fixture or device in another panel once the panels are assembled, for example, on the building site, 3) an installation drawing for each individual connecting medium, and 4) custom drilling instructions for a CNC machine, which, in turn, performs automatic drilling on studs with logic to provide the holes needed to route the connecting media. The custom drilling instruction for CNC may be output at logic 2570.

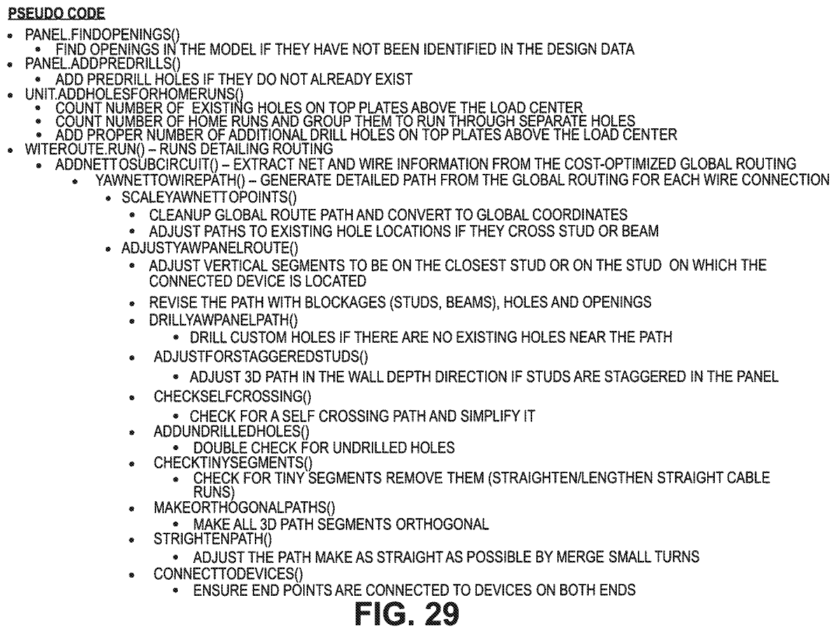

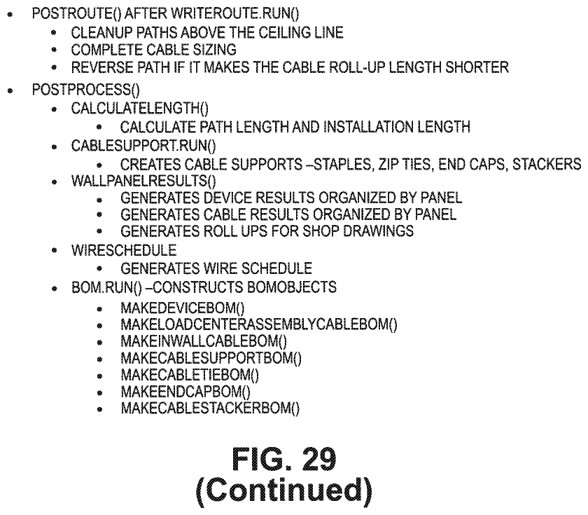

FIG. 29 provides example pseudocode for the logic described with reference to FIG. 25A. It is contemplated similar pseudocode may be written that provides a generic version of the logic described with reference to FIG. 25A that may be applied to an embodiment for connecting medium routing logic 460 for routing connecting media between MEPF devices. Alternatively, is contemplated similar pseudocode may be written that provides a system specific version of the logic described with reference to FIG. 25A that may be applied to an embodiment for connecting medium routing logic 460 for routing a specific type of connecting media between MEPF devices, such as plumbing supply or drain lines between plumbing components or fixtures.

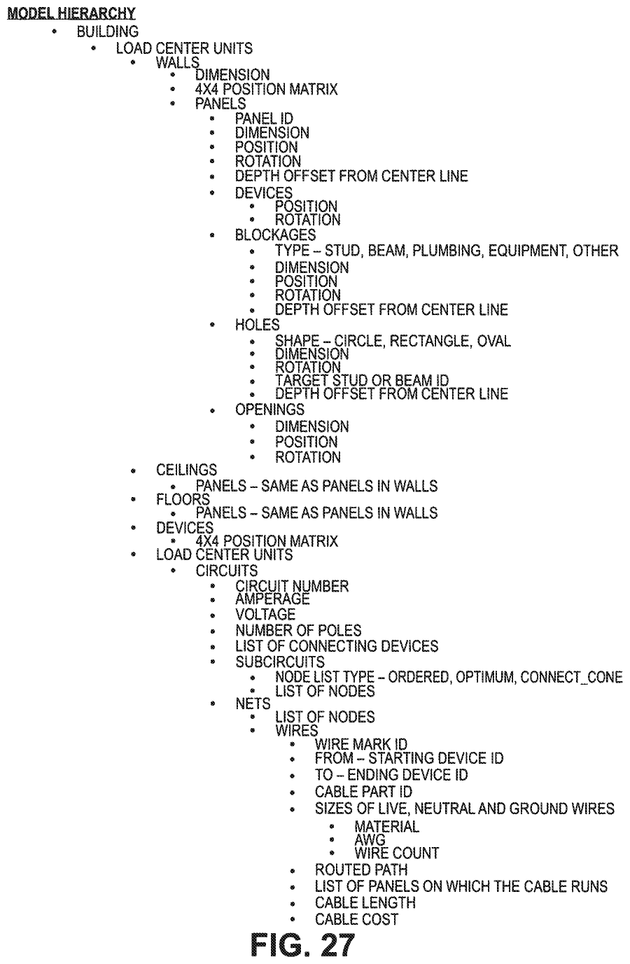

The process performed by the logic blocks described with reference to FIG. 25A provide for updating the structural framing data model 511 with significant details regarding the model. FIG. 27 illustrates a hierarchy for an electrical system model, and where within the hierarchy the information generated by the logic blocks is located, e.g., panel holes, location of load center units, electrical circuits, electrical networks (“nets”), net nodes, and wires between nodes in each net. Similar hierarchies are contemplated for other MEPF systems, such as the plumbing system, HVAC system, fire suppression system, etc.

The Bill of Materials (BOM) report 2556 may be used, e.g., by the BIM software, to identify materials and equipment, as well as quantities and costs thereof. With reference to FIGS. 4A and 25A, logic 2550 may also prepare at least relevant portions of so-called “Shop Drawings” 475, and connecting medium detail and drilling model information 470. Alternatively, such information is part of the report 465 that, in turn, is fed to CAD software 405, and used to update the structural frame model 411, which the BIM plug-in software incorporates into the architectural model, and from which the shop drawings and wiring detail and drilling model may be generated.

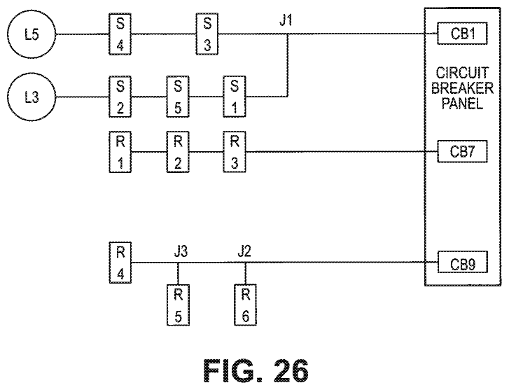

With reference to FIG. 26, the following definitions are utilized by embodiments of the invention for detailed routing logic 2550 to generate the electrical routing detail:

Unit: a set of walls/ceilings/floors that have devices that are served by a single load center. This is not necessarily a structural unit. It is an electrical unit for device placement and wire routing.

Circuit: One circuit is controlled by one breaker. See FIG. 26, in which 3 circuits—#1, #2 and #3 are controlled by CB1, CB7 and CB9, respectively as shown

Subcircuit: a list of connected devices of each branch of a circuit. Examples, with reference to FIG. 26:

Subcircuit A: [ (CB1, S1), {S3, S54}, L5]

Subcircuit B: [ (CB1, S3), {S1, S2, S5}, L3]

Subcircuit C: [ CB7, <R1, R2, R3>]

Subcircuit D: [ CB9, <R4, R5, R6>]

Nomenclature for the above:

[]: connects all nodes in the list in the same order as they appear

{}: connects all nodes in the list in an optimum serial order

<>: connects to all node in the list in an optimum parallel order

( ): connects to only one of the listed nodes

Net: Optimized subcircuit device (or node) connection list determined by device locations and a subcircuit definition. Examples, with reference to FIG. 26:

Circuit #1:
If junction box allowed, Net A: [CB1, J1, S3, S4, L5], Net B: [J1, S1, S5, S2, L3]
If junction box not allowed, Net A: [CB1, S3, S4, L5], Net B: [S3, S1, S5, S2, L3]

Circuit #2, Junction is NOT allowed: Net C: [CB7, R3, R2, R1]

Circuit #3: Junction is allowed: Net D: [CB9, J2, R6], Net E: [J2, J3, R5], Net F: [J3, R4]

Wire: Physical connection between nodes among nodes in the net. Example, with reference to FIG. 26:

Net C consists of 3 wires (CB7-R3, R3-R2 and R2-R1),

Net D consists of 2 wires (CB9-J2 and J2-R6),

Net E consists of 2 wires, and

Net F consists of 1 wire (J3-R4).

Route: Physical path of a wire that connects two nodes (electrical devices).

The above described embodiments can be used or adapted to plan for and design a multitude of MEPF systems, including, for example:

Fire Suppression:

Facility Fire-Suppression Water Service Piping; and

Fire-Suppression Sprinkler Systems.

Plumbing:

Domestic Water Piping (This would include pex, metal and plastic piping and/or hoses);

Sanitary Waste and Vent Piping;

Facility Storm Drainage Piping;

General Service Compressed-Air Piping;

Vacuum Piping for Laboratory and Healthcare Facilities;

Gas Piping for Laboratory and Healthcare Facilities;

Expansion joints for Piping Systems that convey high temperature substances such as steam or exhaust gases, fluids under pressure, or to absorb movement and vibration or mechanical changes; and

Processed Water Piping for Laboratory and Healthcare Facilities including Distilled-Water Piping, Reverse-Osmosis Water Piping, and Deionized-Water Piping.

Heating, Ventilating, and Air Conditioning (HVAC):

Hydronic Piping and Pumps including Hydronic Piping, Steam and Condensate Heating Piping

Facility Fuel Piping including Facility Fuel-Oil Piping, Facility Natural-Gas Piping, and Facility Liquefied-Petroleum Gas Piping;

Refrigerant Piping;

HVAC Ducts and Casings, including Metal Ducts such as Rectangular Metal Ducts and Round and Flat-Oval Spiral Ducts, and Nonmetal Ducts including Fibrous-Glass Ducts and Thermoset Fiberglass-Reinforced Plastic Ducts;

Flexible Ducts;

Expansion joints for Ducted Air Systems; and

Radiant-Heating Hydronic Piping.

Electrical:

Medium-Voltage Cables;

Low-Voltage Electrical Power Conductors and Cables;

Temporary Power and Lighting

Raceway and Boxes for Electrical Systems (including conduits as conduit is raceway but a raceway is not always conduit);

Cable Trays for Electrical Systems;

Underfloor Raceways for Electrical Systems; and

Underground Ducts and Raceways for Electrical Systems;

Communications (low-voltage wiring);

Conduits and Backboxes for Communications Systems; Cable Trays for Communications Systems;

Underground Ducts and Raceways for Communications Systems;

Communications Backbone Cabling; and

Communications Horizontal Cabling.

### Conclusion

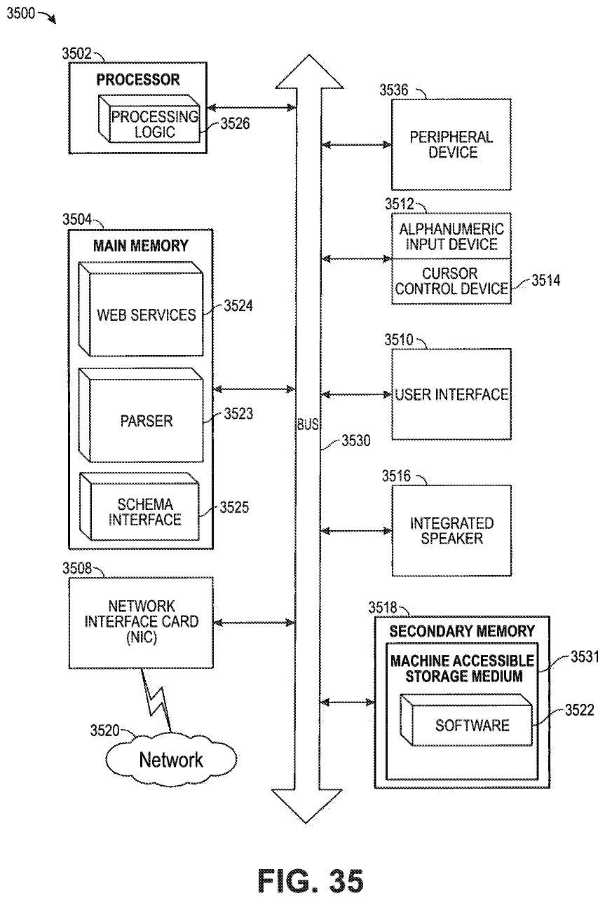

FIG. 35 illustrates a diagrammatic representation of a machine 3500 in the exemplary form of a computer system, in accordance with one embodiment, within which a set of instructions, for causing the machine 3500 to perform any one or more of the methodologies discussed herein, may be executed. In alternative embodiments, the machine may be connected, networked, interfaced, etc., with other machines in a Local Area Network (LAN), a Wide Area Network, an intranet, an extranet, or the Internet. The machine may operate in the capacity of a server or a client machine in a client-server network environment, or as a peer machine in a peer to peer (or distributed) network environment. Certain embodiments of the machine may be in the form of a personal computer (PC), a tablet PC, a set-top box (STB), a Personal Digital Assistant (PDA), a cellular telephone, a web appliance, a server, a network router, switch or bridge, computing system, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 3500 includes a processor 3502, a main memory 3504 (e.g., read-only memory (ROM), flash memory, dynamic random access memory (DRAM) such as synchronous DRAM (SDRAM) or Rambus DRAM (RDRAM), etc., static memory such as flash memory, static random access memory (SRAM), etc.), and a secondary memory 3518, which communicate with each other via a bus 3530. Main memory 3504 includes information and instructions and software program components necessary for performing and executing the functions with respect to the various embodiments of the systems, methods for implementing embodiments of the invention described herein. Instructions 3523 may be stored within main memory 3504. Main memory 3504 and its sub-elements are operable in conjunction with processing logic 3526 and/or software 3522 and processor 3502 to perform the methodologies discussed herein.

Processor 3502 represents one or more general-purpose processing devices such as a microprocessor, central processing unit, or the like. More particularly, the processor 3502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 3502 may also be one or more special-purpose processing devices such as an application specific integrated circuit (ASIC), a field programmable gate array (FPGA), a digital signal processor (DSP), network processor, or the like. Processor 3502 is configured to execute the processing logic 3526 for performing the operations and functionality which are discussed herein.

The computer system 3500 may further include one or more network interface cards 3508 to interface with the computer system 3500 with one or more networks 3520. The computer system 3500 also may include a user interface 3510 (such as a video display unit, a liquid crystal display (LCD), or a cathode ray tube (CRT)), an alphanumeric input device 3512 (e.g., a keyboard), a cursor control device 3514 (e.g., a mouse), and a signal generation device 3516 (e.g., an integrated speaker). The computer system 3500 may further include peripheral device 3536 (e.g., wireless or wired communication devices, memory devices, storage devices, audio processing devices, video processing devices, etc.).

The secondary memory 3518 may include a non-transitory machine-readable storage medium (or more specifically a non-transitory machine-accessible storage medium) 3531 on which is stored one or more sets of instructions (e.g., software 3522) embodying any one or more of the methodologies or functions described herein. Software 3522 may also reside, or alternatively reside within main memory 3504, and may further reside completely or at least partially within the processor 3502 during execution thereof by the computer system 3500, the main memory 3504 and the processor 3502 also constituting machine-readable storage media. The software 3522 may further be transmitted or received over a network 3520 via the network interface card 3508.

Some portions of this detailed description are presented in terms of algorithms and representations of operations on data within a computer memory. These algorithmic descriptions and representations are the means used by those skilled in the data processing arts to most effectively convey the substance of their work to others skilled in the art. An algorithm is here, and generally, conceived to be a sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from this discussion, it is appreciated that throughout the description, discussions utilizing terms such as “processing” or “computing” or “calculating” or “determining” or “displaying” or the like, refer to the action and processes of a computer system or computing platform, or similar electronic computing device(s), that manipulates and transforms data represented as physical (electronic) quantities within the computer system's registers and memories into other data similarly represented as physical quantities within the computer system memories or registers or other such information storage, transmission or display devices.

In addition to various hardware components depicted in the figures and described herein, embodiments further include various operations which are described below. The operations described in accordance with such embodiments may be performed by hardware components or may be embodied in machine-executable instructions, which may be used to cause a general-purpose or special-purpose processor programmed with the instructions to perform the operations. Alternatively, the operations may be performed by a combination of hardware and software, including software instructions that perform the operations described herein via memory and one or more processors of a computing platform.

Embodiments of invention also relate to apparatuses for performing the operations herein. Some apparatuses may be specially constructed for the required purposes, or may comprise a general purpose computer(s) selectively activated or configured by a computer program stored in the computer(s). Such a computer program may be stored in a computer readable storage medium, such as, but not limited to, any type of disk including optical disks, CD-ROMs, DVD-ROMs, and magnetic-optical disks, read-only memories (ROMs), random access memories (RAMs), EPROMs, EEPROMs, NVRAMs, magnetic or optical cards, or any type of media suitable for storing electronic instructions, and each coupled to a computer system bus.

The algorithms presented herein are not inherently related to any particular computer or other apparatus. Various general purpose systems may be used with programs in accordance with the teachings herein, or it may prove convenient to construct more specialized apparatus to perform the required methods. The structure for a variety of these systems appears from the description herein. In addition, embodiments of the invention are not described with reference to any particular programming language. It will be appreciated that a variety of programming languages may be used to implement the embodiments of the invention as described herein.

A machine-readable medium includes any mechanism for storing or transmitting information in a form readable by a machine (e.g., a computer). For example, a machine-readable medium includes read only memory (“ROM”); random access memory (“RAM”); magnetic disk storage media; optical storage media; flash memory devices, etc.

Although the invention has been described and illustrated in the foregoing illustrative embodiments, it is understood that the present disclosure has been made only by way of example, and that numerous changes in the details of implementation of the invention can be made without departing from the spirit and scope of the invention, which is only limited by the claims that follow. Features of the disclosed embodiments can be combined and rearranged in various ways.

What is claimed is:

1. A method for defining a route for a connecting medium through a three-dimensional building, the method comprising:
modeling the three-dimensional building as:
a two-dimensional array of panels, wherein any two panels in the array of panels are connected panels if a connecting medium can be directly routed from one panel to the other panel;
a set of coordinates for each of one or more panels in the array of panels where a connecting medium can enter or exit the panel; and
a union of the respective set of coordinates for each of the one or more connected panels in the array of panels where a connecting medium can be routed between the connected panels; and
selecting one or more panels in the array through which to route the connecting medium based on the unions of the respective set of coordinates for each of the one or more connected panels in the array of panels.

2. The method of claim 1, wherein the set of coordinates for each of one or more panels in the array of panels where a connecting medium can enter or exit the panel comprise one of a side edge, a front or a back edge, and an area edge of the panel.

3. The method of claim 1, further comprising:
modeling each panel in the two-dimensional array of panels as a two-dimensional array of quadrilateral cells;
assigning a cost to each cell in the array of cells for the panel; and
calculating a route for the connecting medium through each panel based on the assigned costs of the cells in the array of cells for the panel.

4. The method of claim 3, wherein modeling each panel in the two-dimensional array of panels as the two-dimensional array of quadrilateral cells comprises modeling each panel in the two-dimensional array of panels as a two-dimensional array of quadrilateral cells aligned with a structural design of a corresponding physical panel in the three-dimensional building.

5. The method of claim 3, wherein selecting one or more panels in the array through which to route the connecting medium based on the unions of the respective set of coordinates for each of the one or more connected panels in the array of panels comprises selecting one or more panels in the array through which to route the connecting medium further based on the defined route for the connecting medium through each panel based on the assigned costs of the cells in the array of cells for the panel.

6. The method of claim 3, further comprising assigning a cost to each side of each cell in the array of cells for the panel; and
wherein assigning the cost to each cell in the array of cells comprises assigning the cost to each cell based on the assigned cost to each side of the cell.

7. The method of claim 3, wherein calculating the route for the connecting medium through each panel based on the assigned costs of the cells in the array of cells for the panel comprises calculating a lowest cost route for the connecting panel through each panel based on the assigned costs of the cells in the array of cells for the panel.

8. A method for specifying a location for each of a plurality of MEPF objects in a model for a three-dimensional (3D) building, the method comprising:
determining available locations in one or more of a plurality of two-dimensional (2D) panels that comprise the 3D building at which a MEPF object can be located, according to an architectural model (AM) of the 3D building and a data model of the 2D panels;
specifying the location for each of the plurality of MEPF objects in one or more of the plurality of 2D panels based on the determined available locations in the one or more 2D panels; and
adding to the data model of the 2D panels the specified location for each of the plurality of MEPF objects in one or more of the plurality of 2D panels.

9. The method of claim 8, further comprising receiving the architectural model (AM) of the 3D building, the AM comprising structural design information and MEPF design information for the 3D building.

10. The method of claim 9, further comprising receiving the data model for the plurality of two-dimensional (2D) panels that comprise the 3D building.

11. The method of claim 8, wherein determining available locations in one or more of the plurality of two-dimensional (2D) panels that comprise the 3D building at which the MEPF object can be located, according to the architectural model (AM) of the 3D building and the data model of the 2D panels comprises:
determining structural framing data and area blockages or restrictions in each 2D panel;
determining an unblocked or unrestricted space for the MEPF object; and
identifying a nearest structural framing data member or stud, and location thereon, at which to mount the MEPF object.

12. The method of claim 11, wherein identifying a nearest structural framing data member or stud, and location thereon, at which to mount the MEPF object comprises identifying a structural framing data member or stud, and location thereon, at which to mount the MEPF object, that results in a shortest or most cost-effective path for a connecting medium that couples the MEPF object to an MEPF system.

13. A method for defining a route for a connecting medium between MEPF objects in an architectural model (AM) for a three-dimensional (3D) building, the method comprising:
receiving structural framing data for a plurality of two-dimensional (2D) panels that comprise the 3D building based on the AM, the structural framing data comprising a location for each of a plurality of MEPF object in one or more of the plurality of 2D panels;
determining available areas in one or more of the plurality of 2D panels through which a connecting medium can be routed between respective locations of two or more of the plurality of MEPF objects;
receiving connecting medium routing rules;
defining a route for a connecting medium between respective locations of two or more of the plurality of MEPF objects in one or more of the plurality of 2D panels based on:
the location for each of a plurality of MEPF objects in one or more of the plurality of 2D panels;
the determined available areas in one or more of the plurality of 2D panels through which the connecting medium can be routed between respective locations of two or more of the plurality of MEPF objects; and
the received connecting medium routing rules.

14. The method of claim 13, wherein receiving connecting medium routing rules comprises:
receiving connecting medium routing information for each of the plurality of 2D panels; and
receiving detailed connecting medium routing rules; and
wherein defining the route for the connecting medium between respective locations of two or more of the plurality of MEPF objects in one or more of the plurality of 2D panels based on the received connecting medium routing rules comprises defining the route for the connecting medium between respective locations of two or more of the plurality of MEPF objects in one or more of the plurality of 2D panels based on the received connecting medium routing information for each of the plurality of 2D panels, and the received detailed connecting routing rules

15. The method of claim 14, wherein receiving connecting medium routing information for each of the plurality of 2D panels comprises receiving cost-optimized connecting medium routing information for each of the plurality of 2D panels; and
wherein defining the route for the connecting medium between respective locations of two or more of the plurality of MEPF objects in one or more of the plurality of 2D panels based on the received connecting medium routing information for each of the plurality of 2D panels comprises defining the route for the connecting medium between respective locations of two or more of the plurality of MEPF objects in one or more of the plurality of 2D panels based on the received cost-optimized connecting medium routing information for each of the plurality of 2D panels.

16. The method of claim 13, further comprising:
receiving the architectural model (AM) of the 3D building, the AM comprising structural design information, and MEPF design information.

17. The method of claim 13, wherein determining the available areas in one or more of the plurality of 2D panels through which the connecting medium can be routed between respective locations of two or more of the plurality of MEPF objects comprises:
determining structural framing data and area blockages or restrictions in each panel; and
determining an unblocked or unrestricted space for the connecting medium.

18. The method of claim 17, wherein determining the available areas in one or more of the plurality of 2D panels through which the connecting medium can be routed between respective locations of two or more of the plurality of MEPF objects further comprises identifying a nearest structural framing data member or stud, and a set of coordinates thereon, at which to affix the connecting medium.

19. The method of claim 13, wherein determining the available areas in one or more of the plurality of 2D panels through which the connecting medium can be routed between respective locations of two or more of the plurality of MEPF objects comprises determining the available areas in one or more of the plurality of 2D panels through which the connecting medium can be routed between respective locations of two or more of the plurality of MEPF objects that results in a shortest or most cost-effective path for the connecting medium.

20. Non-transitory computer readable storage media having instructions stored thereon that, when executed by a processor of a system, the instructions cause the system to perform operations for defining a route for a connecting medium through a three-dimensional building, the method comprising:
modeling the three-dimensional building as:
a two-dimensional array of panels, wherein any two panels in the array of panels are connected panels if a connecting medium can be directly routed from one panel to the other panel;
a set of coordinates for each of one or more panels in the array of panels where a connecting medium can enter or exit the panel; and
a union of the respective set of coordinates for each of the one or more connected panels in the array of panels where a connecting medium can be routed between the connected panels; and
selecting one or more panels in the array through which to route the connecting medium based on the unions of the respective set of coordinates for each of the one or more connected panels in the array of panels.

21. The non-transitory computer readable storage media of claim 20, wherein the set of coordinates for each of one or more panels in the array of panels where a connecting medium can enter or exit the panel comprise one of a side edge, a front or a back edge, and an area edge of the panel.

22. The non-transitory computer readable storage media of claim 20, further comprising:
modeling each panel in the two-dimensional array of panels as a two-dimensional array of quadrilateral cells;
assigning a cost to each cell in the array of cells for the panel; and
calculating a route for the connecting medium through each panel based on the assigned costs of the cells in the array of cells for the panel.

23. The non-transitory computer readable storage media of claim 22, wherein modeling each panel in the two-dimensional array of panels as the two-dimensional array of quadrilateral cells comprises modeling each panel in the two-dimensional array of panels as a two-dimensional array of quadrilateral cells aligned with a structural design of a corresponding physical panel in the three-dimensional building.

24. The non-transitory computer readable storage media of claim 22, wherein selecting one or more panels in the array through which to route the connecting medium based on the unions of the respective set of coordinates for each of the one or more connected panels in the array of panels comprises selecting one or more panels in the array through which to route the connecting medium further based on the defined route for the connecting medium through each panel based on the assigned costs of the cells in the array of cells for the panel.

25. The non-transitory computer readable storage media of claim 22, further comprising assigning a cost to each side of each cell in the array of cells for the panel; and
wherein assigning the cost to each cell in the array of cells comprises assigning the cost to each cell based on the assigned cost to each side of the cell.

26. The non-transitory computer readable storage media of claim 22, wherein calculating the route for the connecting medium through each panel based on the assigned costs of the cells in the array of cells for the panel comprises calculating a lowest cost route for the connecting panel through each panel based on the assigned costs of the cells in the array of cells for the panel.

27. Non-transitory computer readable storage media having instructions stored thereon that, when executed by a processor of a system, the instructions cause the system to perform operations for specifying a location for each of a plurality of MEPF objects in a model for a three-dimensional (3D) building, the method comprising:
determining available locations in one or more of a plurality of two-dimensional (2D) panels that comprise the 3D building at which a MEPF object can be located, according to an architectural model (AM) of the 3D building and a data model of the 2D panels;
specifying the location for each of the plurality of MEPF objects in one or more of the plurality of 2D panels based on the determined available locations in the one or more 2D panels; and
adding to the data model of the 2D panels the specified location for each of the plurality of MEPF objects in one or more of the plurality of 2D panels.

28. The non-transitory computer readable storage media of claim 27, further comprising receiving the architectural model (AM) of the 3D building, the AM comprising structural design information and MEPF design information for the 3D building.

29. The non-transitory computer readable storage media of claim 28, further comprising receiving the data model for the plurality of two-dimensional (2D) panels that comprise the 3D building.

30. The non-transitory computer readable storage media of claim 27, wherein determining available locations in one or more of the plurality of two-dimensional (2D) panels that comprise the 3D building at which the MEPF object can be located, according to the architectural model (AM) of the 3D building and the data model of the 2D panels comprises:
determining structural framing data and area blockages or restrictions in each 2D panel;
determining an unblocked or unrestricted space for the MEPF object; and
identifying a nearest structural framing data member or stud, and location thereon, at which to mount the MEPF object.

31. The non-transitory computer readable storage media of claim 30, wherein identifying a nearest structural framing data member or stud, and location thereon, at which to mount the MEPF object comprises identifying a structural framing data member or stud, and location thereon, at which to mount the MEPF object, that results in a shortest or most cost-effective path for a connecting medium that couples the MEPF object to an MEPF system.

32. Non-transitory computer readable storage media having instructions stored thereon that, when executed by a processor of a system, the instructions cause the system to perform operations for defining a route for a connecting medium between MEPF objects in an architectural model (AM) for a three-dimensional (3D) building, the method comprising:
receiving structural framing data for a plurality of two-dimensional (2D) panels that comprise the 3D building based on the AM, the structural framing data comprising a location for each of a plurality of MEPF object in one or more of the plurality of 2D panels;
determining available areas in one or more of the plurality of 2D panels through which a connecting medium can be routed between respective locations of two or more of the plurality of MEPF objects;
receiving connecting medium routing rules;
defining a route for a connecting medium between respective locations of two or more of the plurality of MEPF objects in one or more of the plurality of 2D panels based on:
the location for each of a plurality of MEPF objects in one or more of the plurality of 2D panels;
the determined available areas in one or more of the plurality of 2D panels through which the connecting medium can be routed between respective locations of two or more of the plurality of MEPF objects; and
the received connecting medium routing rules.

33. The non-transitory computer readable storage media of claim 32, wherein receiving connecting medium routing rules comprises:
receiving connecting medium routing information for each of the plurality of 2D panels; and
receiving detailed connecting medium routing rules; and
wherein defining the route for the connecting medium between respective locations of two or more of the plurality of MEPF objects in one or more of the plurality of 2D panels based on the received connecting medium routing rules comprises defining the route for the connecting medium between respective locations of two or more of the plurality of MEPF objects in one or more of the plurality of 2D panels based on the received connecting medium routing information for each of the plurality of 2D panels, and the received detailed connecting routing rules

34. The non-transitory computer readable storage media of claim 33, wherein receiving connecting medium routing information for each of the plurality of 2D panels comprises receiving cost-optimized connecting medium routing information for each of the plurality of 2D panels; and
wherein defining the route for the connecting medium between respective locations of two or more of the plurality of MEPF objects in one or more of the plurality of 2D panels based on the received connecting medium routing information for each of the plurality of 2D panels comprises defining the route for the connecting medium between respective locations of two or more of the plurality of MEPF objects in one or more of the plurality of 2D panels based on the received cost-optimized connecting medium routing information for each of the plurality of 2D panels.

35. The non-transitory computer readable storage media of claim 32, further comprising:
receiving the architectural model (AM) of the 3D building, the AM comprising structural design information, and MEPF design information.

36. The non-transitory computer readable storage media of claim 32, wherein determining the available areas in one or more of the plurality of 2D panels through which the connecting medium can be routed between respective locations of two or more of the plurality of MEPF objects comprises:
determining structural framing data and area blockages or restrictions in each panel; and
determining an unblocked or unrestricted space for the connecting medium.

37. The non-transitory computer readable storage media of claim 36, wherein determining the available areas in one or more of the plurality of 2D panels through which the connecting medium can be routed between respective locations of two or more of the plurality of MEPF objects further comprises identifying a nearest structural framing data member or stud, and a set of coordinates thereon, at which to affix the connecting medium.

38. The non-transitory computer readable storage media of claim 32, wherein determining the available areas in one or more of the plurality of 2D panels through which the connecting medium can be routed between respective locations of two or more of the plurality of MEPF objects comprises determining the available areas in one or more of the plurality of 2D panels through which the connecting medium can be routed between respective locations of two or more of the plurality of MEPF objects that results in a shortest or most cost-effective path for the connecting medium.
